(19) United States
(12) Patent Application Publication
(10) Pub. No.: US 2026/0169349 A1
(43) Pub. Date: Jun. 18, 2026

(54) MULTI-WAVELENGTH LASER LIGHT SOURCE, METHOD OF MANUFACTURING THE SAME, AND SILICON PHOTONIC INTEGRATED CIRCUIT APPARATUS USING THE SAME

(71) Applicant: SAMSUNG ELECTRONICS CO., LTD., Suwon-si (KR)

(72) Inventors: Dongho KIM, Suwon-si (KR); Choongho RHEE, Suwon-si (KR); Joosung KIM, Suwon-si (KR); Changyoung PARK, Suwon-si (KR); Sanghun LEE, Suwon-si (KR)

(73) Assignee: SAMSUNG ELECTRONICS CO., LTD., Suwon-si (KR)

(21) Appl. No.: 19/423,371

(22) Filed: Dec. 17, 2025

(30) Foreign Application Priority Data
Dec. 18, 2024 (KR) 10-2024-0190448

(51) Int. Cl. G02F 1/35; H01S 5/026; H01S 5/12; H01S 5/343

(52) U.S. Cl. CPC G02F 1/3513; H01S 5/026; H01S 5/12; H01S 5/343; G02F 2203/56

(57) ABSTRACT

Provided is a multi-wavelength laser light source including a silicon substrate that includes a multi-groove pattern, a laser element, based on a III-V compound semiconductor material and being configured to generate a pump laser light, comprising a buffer layer crystal grown with respect to the multi-groove pattern and a light emitting layer structure epitaxially grown on the buffer layer and comprising a quantum well structure that comprises quantum barrier layers and quantum well layers stacked alternately multiple times, a micro-resonator on the silicon substrate, having anomalous group velocity dispersion (GVD), and being configured to generate a soliton frequency comb with respect to the pump laser light, and a waveguide on the silicon substrate and enabling optical coupling to the micro-resonator and transmitting the pump laser light input from the laser element to the micro-resonator, wherein the micro-resonator generates laser light having discontinuous wavelength bands of the soliton frequency comb.

### CROSS-REFERENCE TO RELATED APPLICATION

This application is based on and claims priority under 35 U.S.C. § 119 to Korean Patent Application No. 10-2024-0190448, filed on Dec. 18, 2024, in the Korean Intellectual Property Office, the disclosure of which is incorporated by reference herein in its entirety.

### BACKGROUND

### 1. Field

The disclosure relates to a multi-wavelength laser light source, a method of manufacturing the same, and a silicon photonic integrated circuit (PIC) apparatus using the same.

### 2. Description of Related Art

A photonic integrated circuit (PIC) that converts electrical signals into light signals is required for mass transmission of light signals. In addition, mass transmission of light signals is performed using wavelength division multiplexing (WDM), in which several different wavelengths are used as respective transmission channels.

Thus, wideband characteristics are required for large-capacity transmission, and to this end, multi-wavelength light sources are required. Although it is essential to apply multi-wavelength light sources using III-V compound semiconductor materials to silicon-based systems, it is difficult to manufacture directly multi-wavelength light sources using III-V compound semiconductor materials on silicon substrates, and thus multi-wavelength light sources are applied using external light sources or through bonding. However, it is difficult to accurately align a multi-wavelength light source with a waveguide in the PIC using external light sources or through bonding, and coupling loss due to misalignment occurs when coupled with a waveguide 170, and thus power loss is likely to occur. Therefore, it is necessary to integrate a light source in the PIC.

### SUMMARY

Provided are an integrated type multi-wavelength laser light source for light connection and a method of manufacturing the same.

Provided is a silicon photonic integrated circuit (PIC) apparatus with an integrated type multi-wavelength laser light source for light connection applied.

Additional aspects will be set forth in part in the description which follows and, in part, will be apparent from the description, or may be learned by practice of the presented embodiments of the disclosure.

According to an aspect of one or more embodiments, there is provided a multi-wavelength laser light source including a silicon substrate including a multi-groove pattern in a partial region of the silicon substrate, a laser element based on a III-V compound semiconductor material and configured to generate a pump laser light, the laser element comprising a buffer layer crystal grown with respect to the multi-groove pattern and a light emitting layer structure epitaxially grown on the buffer layer and comprising a quantum well structure that comprises quantum barrier layers and quantum well layers stacked alternately multiple times, a micro-resonator on the silicon substrate, the micro-resonator having anomalous group velocity dispersion (GVD) and to being configured to generate a soliton frequency comb with respect to the pump laser light, and a waveguide on the silicon substrate, the waveguide being configured to enable optical coupling to the micro-resonator and to transmit the pump laser light input from the laser element to the micro-resonator, wherein the micro-resonator is further configured to generate laser light having a plurality of discontinuous wavelength bands of the soliton frequency comb.

The micro-resonator may include a racetrack concentric resonator including an inner ring and an outer ring spaced apart from the inner ring.

An effective light path length of the inner ring may be equal to an effective light path length of the outer ring.

A ring cross-sectional width of the inner ring may be greater than a ring cross-sectional width of the outer ring.

Each of the inner ring and the outer ring may include at least one of silicon nitride (Si₃N₄), Silica, lithium niobium oxide (LiNbO₃), tantalum oxide (Ta₂O₅), silicon (Si), gallium phosphide (GaP), aluminum indium nitride (AlN), aluminum gallium arsenide (AlGaAs), indium phosphide (InP), or titanium oxide (TiO₂).

The multi-groove pattern may have a multi-V groove shape.

According to another aspect of one or more embodiments, there is provided a method of manufacturing a multi-wavelength laser light source, the method including forming a multi-groove pattern in a partial region of a silicon substrate, forming a laser element, based on a III-V compound semiconductor material and configured to generate a pump laser light by forming a buffer layer crystal grown with respect to the multi-groove pattern and forming a light emitting layer structure epitaxially grown on the buffer layer, the light emitting layer structure including a quantum well structure formed by alternately stacking quantum barrier layers and quantum well layers multiple times, and forming a micro-resonator and a waveguide on the silicon substrate, the waveguide being configured to be optically coupled to the micro-resonator and to have an input end at a level of the quantum well structure of the laser element such that the laser element is configured to input the pump laser light, wherein the micro-resonator is formed to have anomalous group velocity dispersion (GVD), and the micro-resonator is configured to generate a soliton frequency comb with respect to the pump laser light, and wherein the micro-resonator is further configured to generate laser light having a plurality of discontinuous wavelength bands of the soliton frequency comb.

The micro-resonator and the waveguide may be formed in a same process step or different process steps.

The micro-resonator may be a racetrack concentric resonator including an inner ring and an outer ring spaced apart from the inner ring.

The micro-resonator may be formed such that an effective light path length of the inner ring is equal to an effective light path length of the outer ring.

A ring cross-sectional width of the inner ring may be greater than a ring cross-sectional width of the outer ring.

Each of the inner ring and the outer ring may include at least one of silicon nitride (Si₃N₄), Silica, lithium niobium oxide (LiNbO₃), tantalum oxide (Ta₂O₅), silicon (Si), gallium phosphide (GaP), aluminum indium nitride (AlN), aluminum gallium arsenide (AlGaAs), indium phosphide (InP), or titanium oxide (TiO₂).

The multi-groove pattern may have a multi-V groove shape.

According to still another aspect of one or more embodiments, there is provided a silicon photonic integrated circuit (PIC) apparatus including a multi-wavelength laser light source including a laser element on a silicon substrate, the laser element being based on a III-V compound semiconductor material and configured to generate pump laser light, a micro-resonator on the silicon substrate, the micro-resonator being configured to generate a soliton frequency comb with respect to the pump laser light, and a waveguide on the silicon substrate, the waveguide being configured to enable optical coupling to the micro-resonator and to transmit the pump laser light input from the laser element to the micro-resonator, and at least one optical element on the silicon substrate and optically connected to the multi-wavelength laser light source, wherein a multi-groove pattern is in a partial region of the silicon substrate, wherein the laser element comprises a buffer layer crystal grown with respect to the multi-groove pattern of the silicon substrate, and a light emitting layer structure epitaxial grown on the buffer layer and comprising a quantum well structure that comprises quantum barrier layers and quantum well layers alternately stacked multiple times, wherein the micro-resonator has anomalous group velocity dispersion (GVD) on the silicon substrate, and is further configured to generate the soliton frequency comb with respect to the pump laser light, and wherein the micro-resonator included in the multi-wavelength laser light source is configured to generate laser light having a plurality of discontinuous wavelength bands of the soliton frequency comb.

The micro-resonator may be a racetrack concentric resonator including an inner ring and an outer ring spaced apart from the inner ring.

An effective light path length of the inner ring may be equal to an effective light path length of the outer ring.

A ring cross-sectional width of the inner ring may be greater than a ring cross-sectional width of the outer ring.

Each of the inner ring and the outer ring may include at least one of silicon nitride (Si₃N₄), Silica, lithium niobium oxide (LiNbO₃), tantalum oxide (Ta₂O₅), silicon (Si), gallium phosphide (GaP), aluminum indium nitride (AlN), aluminum gallium arsenide (AlGaAs), indium phosphide (InP), or titanium oxide (TiO₂).

The multi-groove pattern may have a multi-V groove shape.

The at least one optical element may include at least one light modulator configured to modulate at least some of the plurality of discontinuous wavelength bands of the laser light traveling through the waveguide and form a modulated soliton frequency comb.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view of a multi-wavelength laser light source according to one or more embodiments;

FIG. 2 is an enlarged perspective view of a laser element of FIG. 1;

FIG. 3 is an enlarged cross-sectional view of a multi-groove pattern portion of FIGS. 1 and 2;

FIG. 4 illustrates a cross-sectional view of a micro-resonator of FIG. 1;

FIG. 5 is a plan view of a micro-resonator according to one or more embodiments;

FIG. 6 shows anomalous dispersion characteristics of a micro-resonator formed in an anti-symmetric mode;

FIG. 7 shows a soliton frequency comb generated with respect to pump laser light in a wavelength band having an anomalous dispersion;

FIG. 8A shows a change in refractive index according to a wavelength in normal dispersion (D<0);

FIG. 8B shows a change in refractive index according to a wavelength in anomalous dispersion (D>0);

FIGS. 9A, 9B, 9C, and 9D show a method of manufacturing a multi-wavelength laser light source according to one or more embodiments;

FIG. 10 is a perspective view of a silicon photonic integrated circuit (PIC) apparatus including a multi-wavelength laser light source according to one or more embodiments;

FIGS. 11, 12, and 13 are cross-sectional views of a laser element according to one or more other embodiments;

FIG. 14 shows a silicon PIC apparatus with a multi-wavelength laser light source applied according to one or more embodiments; and

FIG. 15 is a block diagram of a schematic configuration of an optoelectronic apparatus according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, the embodiments will be described in detail with reference to accompanying drawings. In the drawings, like reference numerals denote like components, and sizes of components in the drawings may be exaggerated for convenience of explanation. The embodiments of the disclosure are capable of various modifications and may be embodied in many different forms.

When a layer, a film, a region, or a panel is referred to as being “on” another element, it may be directly on/under/at left/right sides of the other layer or substrate, or intervening layers may also be present. An expression used in the singular encompasses the expression of the plural, unless it has a clearly different meaning in the context. It will be further understood that when a portion is referred to as “comprising” another component, the portion may not exclude another component but may further comprise another component unless the context states otherwise.

The term “the” and the similar indicative terms may be used in both the singular and the plural. If there is no explicit description of the order of steps constituting a method or no contrary description thereto, these steps may be performed in an appropriate order, and are not limited to the order described.

In addition, the terms “ . . . unit”, “module”, etc. described herein mean a unit that processes at least one function or operation, may be implemented as hardware or software, or may be implemented as a combination of hardware and software.

Connections of lines or connection members between elements shown in the drawings are illustrative of functional connections and/or physical or circuitry connections, and may be redisposed in an actual device, or may be represented as additional various functional connections, physical connections, or circuitry connections.

The use of all examples or example terms is merely for describing the technical concept in detail, and the scope thereof is not limited by these examples or example terms unless limited by the claims.

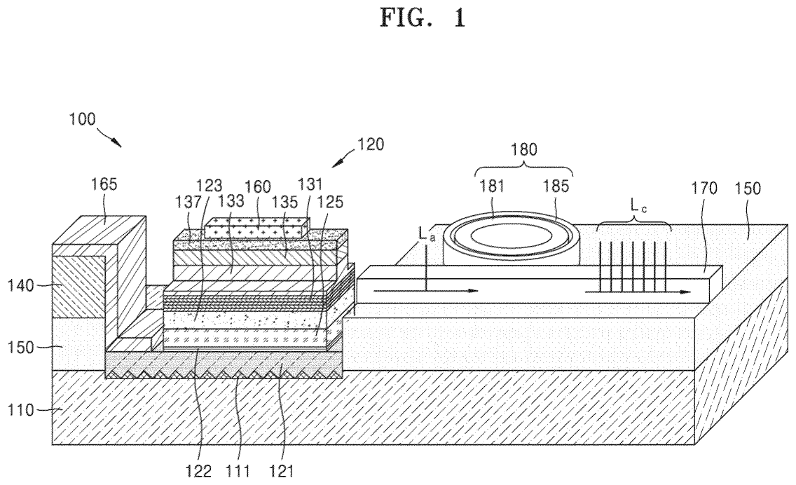

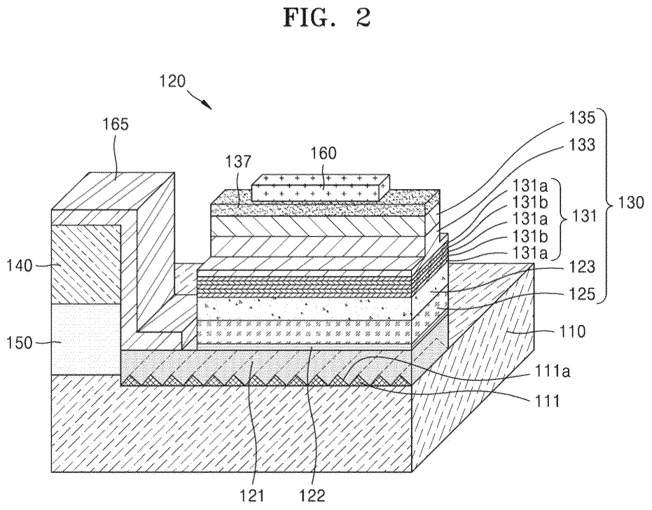

FIG. 1 is a schematically perspective view of a multi-wavelength laser light source 100 according to one or more embodiments. FIG. 2 is an enlarged perspective view of a laser element 120 of FIG. 1.

Referring to FIGS. 1 and 2, the multi-wavelength laser light source 100 may include the laser element 120 based on and including a III-V compound semiconductor material and generating pump laser light La, a micro-resonator 180 coupled to the pump laser light La to form a soliton frequency comb, and a waveguide 170 transferring the pump laser light La to the micro-resonator 180. The laser element 120, the waveguide 170, and the micro-resonator 180 may be formed on a silicon substrate 110. The laser element 120 may be based on and include the III-V compound semiconductor material, and formed on the silicon substrate 110 by crystal growth with respect to a multi-groove pattern 111 of the silicon substrate 110.

Herein, a direction parallel to a main surface (upper surface or lower surface) of the silicon substrate 110 may be referred to as a horizontal direction, and a direction perpendicular and normal to the horizontal direction may be referred to as a vertical direction.

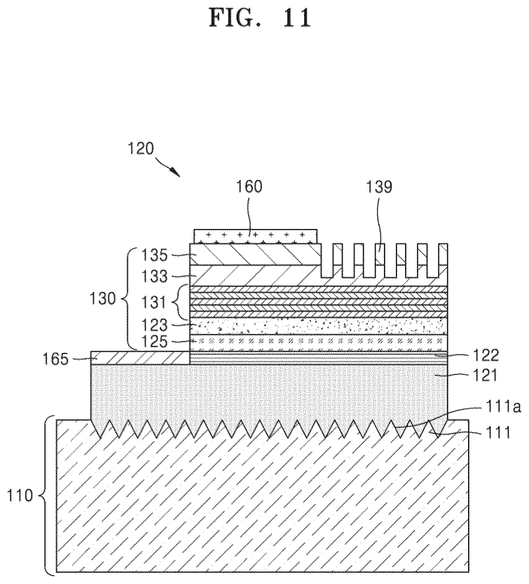

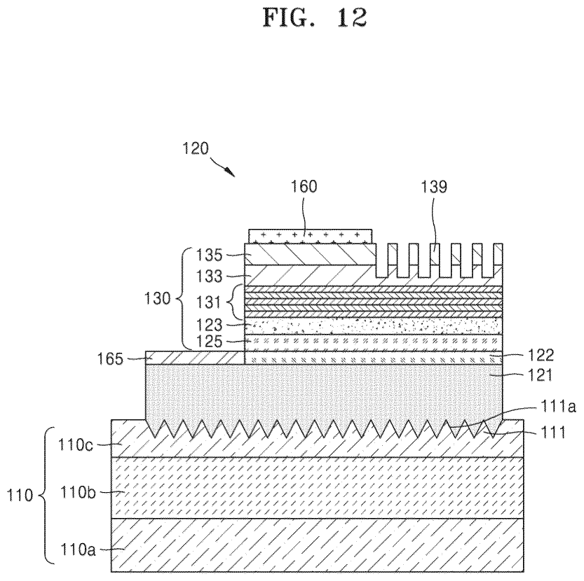

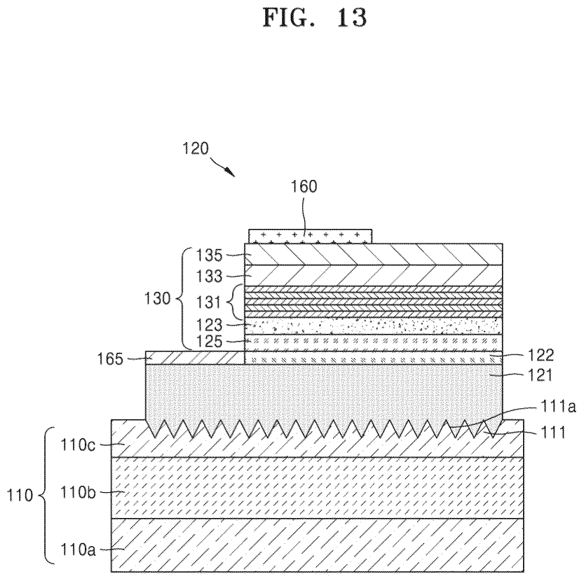

The silicon substrate 110 may be a substrate (see FIGS. 2 and 11) formed from a silicon material or a silicon-on-insulator (SOI) substrate (see FIGS. 12 and 13). The multi-groove pattern 111 for forming the laser element 120 by crystal growth may be formed in a partial region of the silicon substrate 110. The multi-groove pattern 111 may be formed of silicon material. For example, when the silicon substrate 110 is the SOI substrate, as shown in FIGS. 12 and 13, the multi-groove pattern 111 may be formed by patterning a partial region of a silicon layer 110c on an insulating layer 110b. When the silicon substrate 110 is formed of silicon material as shown in FIGS. 2 and 11, the multi-groove pattern 111 may be formed by patterning a partial region of the surface of the silicon substrate 110.

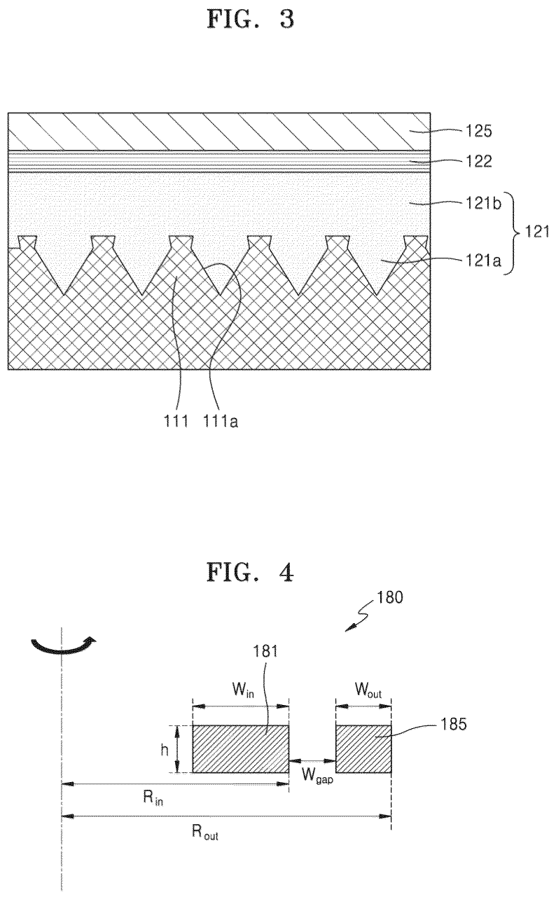

FIG. 3 is an enlarged cross-sectional view of a part of the multi-groove pattern 111 of FIGS. 1 and 2.

As shown in FIG. 3, the multi-groove pattern 111 may be formed in the shape of a multi-V groove. For example, the multi-groove pattern 111 may include multiple V shaped grooves. The multi-groove pattern 111 may include a silicon material. The multi-groove pattern 111 in the shape of the multi-V groove may be formed by, for example, wet etching. Wet etching may be performed, for example, using a KOH or TMAH solution as an etching medium.

The multi-groove pattern 111 may correspond to a multi-Si (111) surface 111a and as the multi-groove pattern 111 is in the shape of the multi-V groove, a Si (111) surface and a Si (−111) surface are alternately repeated, and may be expressed as a multi-Si (111) surfaces). With respect to the multi-Si (111) surface 111a of the multi-groove pattern 111, a compound semiconductor material with a relatively large lattice constant difference from silicon, such as, for example, the III-V compound semiconductor material, may be crystal-grown. By crystal growth of the III-V compound semiconductor material with respect to the multi-groove pattern 111, the laser element 120 based on and including the III-V compound semiconductor material may be directly grown on the silicon substrate 110. For example, the laser element 120 may directly contact the silicon substrate 110.

Referring back to FIGS. 1 and 2, the laser element 120 may include a buffer layer 121 crystal-grown with respect to the multi-groove pattern 111 of the silicon substrate 110, and a light emitting layer structure 130 formed on the buffer layer 121 and including a quantum well structure 131, may be based on and include the III-V compound semiconductor material, and may generate the pump laser light La. The light emitting layer structure 130 may further include at least one of a first type semiconductor layer 125 and a first clad layer 123 between the buffer layer 121 and the quantum well structure 131. In addition, the light emitting layer structure 130 may further include at least one of a second clad layer 133 and a second type semiconductor layer 135, which is of a conductivity type opposite to a first type on the quantum well structure 131. Hereinafter, an example in which the light emitting layer structure 130 is a structure in which the first type semiconductor layer 125, the first clad layer 123, the quantum well structure 131, the second clad layer 133, and the second type semiconductor layer 135 are sequentially stacked on the buffer layer 121 will be described, but is not limited thereto. The buffer layer 121, the first type semiconductor layer 125, the first clad layer 123, the quantum well structure 131, the second clad layer 133, and the second type semiconductor layer 135 may be based on and include the III-V compound semiconductor material. The light emitting layer structure 130, that is, a stack structure of the first type semiconductor layer 125, the first clad layer 123, the quantum well structure 131, the second clad layer 133, and the second type semiconductor layer 135, may be epitaxially grown on the buffer layer 121.

The buffer layer 121 may be crystal-grown with respect to the multi-groove pattern 111 of the silicon substrate 110 during a deposition process. The buffer layer 121 may include a III-V compound semiconductor material, for example, a compound semiconductor material including at least two of indium (In), gallium (Ga), aluminum (Al), arsenic (As), or phosphorus (P). As another example, the buffer layer 121 may include a multilayer structure of the compound semiconductor material including at least two of indium (In), gallium (Ga), aluminum (Al), arsenic (As), or phosphorus (P). The buffer layer 121 may include, for example, GaAs, InGaAs, and/or InP. For example, when the silicon substrate 110 is an n-type silicon substrate, the buffer layer 121 may include n-GaAs. However, embodiments are not limited thereto.

The buffer layer 121 may be crystal-grown with respect to the multi-groove pattern 111 to fill the multi-V groove and be formed to a height greater than or equal to a height of the multi-V groove in the vertical direction. The buffer layer 121 may include an aspect ratio trapping (ART) layer 121a filling the multi-V groove and a nano-ridge epitaxy (NRE) layer 121b formed by crystal growth of the ART layer 121a. The ART layer 121a may correspond to a part of the buffer layer 121 formed to fill the multi-V groove, and the NRE layer 121b may correspond to a part of the buffer layer 121 formed to a certain thickness in the vertical direction after filling the multi-V groove.

The ART layer 121a and the NRE layer 121b may be formed from a compound semiconductor material having at least one different element, or may be formed from the same compound semiconductor material. When the ART layer 121a and the NRE layer 121b are formed from the same compound semiconductor material, the ART layer 121a and the NRE layer 121b may be continuously and integrally formed without an interlayer interface. When the ART layer 121a and the NRE layer 121b are formed from the compound semiconductor material having at least one different element, the ART layer 121a and the NRE layer 121b may be continuously formed without an interlayer interface or an interlayer interface may be formed therebetween. At this time, the ART layer 121a and the NRE layer 121b may include a III-V compound semiconductor material, for example, a compound semiconductor material including at least two of indium (In), gallium (Ga), aluminum (Al), arsenic (As), or phosphorus (P). As another example, the ART layer 121a and the NRE layer 121b may include a multilayer structure of the compound semiconductor material including at least two of indium (In), gallium (Ga), aluminum (Al), arsenic (As), or phosphorus (P). The ART layer 121a and the NRE layer 121b may include, for example, GaAs, InGaAs, or InP.

However, embodiments are not limited thereto. The ART layer 121a may include, for example, GaAs. The NRE layer 121b may include, for example, InGaAs, for example, In_{0.25}GaAs. As another example, the ART layer 121a and the NRE layer 121b may include GaAs.

In this way, defects may be reduced when the buffer layer 121 based on and include the III-V compound semiconductor material with the relatively large lattice constant difference from silicon is crystal-grown on the multi-groove pattern 111 of the silicon substrate 110, thereby enabling relatively high-quality epitaxial growth capable of laser oscillation.

The light emitting layer structure 130, for example, the first type semiconductor layer 125, the first clad layer 123, the quantum well structure 131, the second clad layer 133, and the second type semiconductor layer 135, may be sequentially epitaxially grown on the buffer layer 121 formed in this way.

The quantum well structure 131 of the light emitting layer structure 130 may include a multiple quantum well structure. An emission wavelength may be determined by a combination of semiconductor materials forming the quantum well structure 131, a layer thickness, etc. For example, the quantum well structure 131 may be formed to generate the pump laser light La within a wavelength range of about 950 nm to about 1,750 nm. For example, the quantum well structure 131 may be formed to generate the pump laser light La having a center wavelength of approximately 1,310 nm and a certain wavelength bandwidth.

The quantum well structure 131 may include quantum barrier layers 131a and quantum well layers 131b that are alternately stacked a plurality of times. Each of the quantum barrier layer 131a and the quantum well layer 131b may independently include at least one of indium (In), gallium (Ga), aluminum (Al), arsenic (As), phosphorous (P), silicon (Si), zinc (Zn), or carbon (C). For example, the quantum barrier layer 131a may include InₓGa_{y}Al_{z}As (0.00≤x≤0.50, 0.00≤y, z≤0.95), and the quantum well layer 131b may include InₓGa_{y}Al_{z}As (0.20≤x≤0.60, 0.00≤y, z≤0.95). For example, the quantum well layer 131b may include phosphorus (In), and the content of phosphorus (In) may be in a range of about 0.20 to about 0.55, for example, about 0.45. The quantum barrier layer 131a may selectively include phosphorus (In), and the content of phosphorus (In) may be in a range of about 0.00 to about 0.45, for example, about 0.25. As an example, the quantum well structure 131 may be formed by two or more alternate growths of the quantum barrier layer 131a including GaAs and the quantum well layer 131b including InGaAs, for example, In_{0.45}GaAs.

An emission wavelength band of the quantum well structure 131 may be adjusted by changing at least one of the shape, material, and thickness of the quantum well layer 131b in the vertical direction, and an emission intensity the quantum well structure 131 may be adjusted by changing the number of layers of the quantum well layer 131b.

For example, the quantum well structure 131 may be formed by two or more alternate growths of the quantum barrier layer 131a of about 3 nm or more and the quantum well layer 131b of about 3 nm or more. Each of the quantum barrier layers 131a may be formed to a thickness in the vertical direction of about 3 nm or more, for example, about 3 nm or more and 50 nm or less, and each of the quantum well layers 131b may be formed to a thickness in the vertical direction of about 3 nm or more, for example, about 3 nm or more and 25 nm or less. However, embodiments are not limited thereto, and the quantum barrier layer 131a and the quantum well layer 131b may be formed to have various thicknesses in the vertical direction.

The first type semiconductor layer 125 may be disposed in a lower portion of the quantum well structure 131 in the vertical direction. The first type semiconductor layer 125 may include InP, and may be doped with a first type dopant. The first type semiconductor layer 125 is not limited to InP, but may vary depending on a material of the NRE layer 121b of the buffer layer 121. For example, the first type semiconductor layer 125 may include GaAs, InGaAs, InGaAlAs, or InGaAsP, and may be doped with the first type dopant. For example, the first type semiconductor layer 125 may be doped with an n-type dopant. The first type semiconductor layer 125 may include, for example, InP doped with the n-type dopant. As the n-type dopant, for example, Si, C, germanium (Ge), selenium (Se), or tellurium (Te) may be used. However, embodiments are not limited thereto. The first type semiconductor layer 125 may include a p-type dopant, and, for example, Zn or magnesium (Mg) may be used as the p-type dopant.

The second type semiconductor layer 135 may include InP, and may be doped with a second type dopant. However, embodiments are not limited thereto. For example, the second type semiconductor layer 135 may include InGaAs, InGaAlAs, or

InGaAsP, and may be doped with the second type dopant. For example, the second type semiconductor layer 135 may be doped with the p-type dopant. As the p-type dopant, for example, Zn or Mg may be used. However, embodiments are not limited thereto, and the second type semiconductor layer 135 may include the n-type dopant. As the n-type dopant, for example, Si, C, Ge, Se, or Te may be used.

For example, the first type semiconductor layer 125 may be an n-type InP layer and, for example, may be formed as an n-contact layer in a range of a thickness in the vertical direction of about 0.01 μm or more and about 1 μm or less, and the second type semiconductor layer 135 may include p-type InGaAs or InP layer and, for example, may be formed as a p-contact layer in a range of a thickness in the vertical direction of about 0.01 μm or more and about 1 μm or less.

The first clad layer 123 may confine (capture) light generated in the quantum well structure 131 together with the second clad layer 133. The first clad layer 123 and the second clad layer 133 may be referred to as a separated confinement heterostructure (SCH) layer. The first clad layer 123 and the second clad layer 133 may additionally operate as current diffusion. The thickness in the vertical direction of each of the first clad layer 123 and the second clad layer 133 may be, for example, about 0.01 μm or more and about 1 μm or less.

The first clad layer 123 may include, for example, a material in which a certain dopant is included in at least one of In, Ga, Al, As, P, Si, Zn, and C. The first clad layer 123 may include, for example, a material in which a certain dopant is included in GaAs, InGaAs, InGaAlAs, InGaAsP, or InP. The first clad layer 123 may have a dopant concentration lower than a dopant concentration of the first type semiconductor layer 125.

When the first type semiconductor layer 125 is an n-type semiconductor layer, the first clad layer 123 may be an n-type clad layer. In this case, the first clad layer 123 may include, for example, an n-type dopant such as Si, C, Ge, Se, Te, etc. When the first type semiconductor layer 125 is a p-type semiconductor layer, the first clad layer 123 may be a p-type clad layer. In this case, the first clad layer 123 may include, for example, a p-type dopant such as Zn, Mg, etc.

The second clad layer 133 may include, for example, a material in which a certain dopant is included in at least one of In, Ga, Al, As, P, Si, Zn, and C. The second clad layer 133 may include, for example, a material in which a certain dopant is included in InGaAs, InGaAlAs, InGaAsP, or InP. The second clad layer 133 may have a dopant concentration lower than a dopant concentration of the second type semiconductor layer 135.

When the second type semiconductor layer 135 is a p-type semiconductor layer, the second clad layer 133 may be a p-type clad layer. In this case, the second clad layer 133 may include, for example, a p-type dopant such as Zn, Mg, etc. When the second type semiconductor layer 135 is an n-type semiconductor layer, the second clad layer 133 may be an n-type clad layer. In this case, the second clad layer 133 may include, for example, an n-type dopant such as Si, C, Ge, Se, Te, etc.

As shown in FIGS. 1 and 2, the laser element 120 may further include a capping layer 137 on the light emitting layer structure 130. The capping layer 137 is for preventing damage to the light emitting layer structure 130 when forming a passivation layer prior to manufacturing of an electrical contact structure with respect to the laser element 120. In FIGS. 1 and 2, the capping layer 137 is formed on an upper surface of the second type semiconductor layer 135 in the vertical direction, but the capping layer 137 may also be formed adjacent to and to surround the light emitting layer structure 130 in a horizontal direction.

The capping layer 137 may include a certain dopant. The capping layer 137 may be, for example, a material in which a certain dopant is included in InGaP. When the second type semiconductor layer 135 is a p-type semiconductor layer, the capping layer 137 may be a p-type capping layer, for example, a p-InGaP layer. In this case, the capping layer 137 may include, for example, a p-type dopant such as Zn, Mg, etc. When the second type semiconductor layer 135 is an n-type semiconductor layer, the capping layer 137 may be an n-type capping layer, for example, an n-InGaP layer. In this case, the capping layer 137 may include, for example, an n-type dopant such as Si, C, Ge, Se, Te, etc.

The laser element 120 may further include a first type contact layer 165 and a second type contact layer 160. The first type contact layer 165 may be formed, for example, in a region on the buffer layer 121. As another example, the first type contact layer 165 may be formed to be in contact with the silicon substrate 110. FIGS. 1 and 2 show an example in which the first type contact layer 165 is formed on the buffer layer 121. The second type contact layer 160 may be formed on the second type semiconductor layer 135. As shown in FIGS. 1 and 2, when the capping layer 137 is formed on the second type semiconductor layer 135, the second type contact layer 160 may be formed on the capping layer 137.

The first type contact layer 165 may be formed of, for example, a semiconductor material, and may be doped with a first type at a relatively high concentration. When the buffer layer 121 is an n-type, the first type contact layer 165 may be doped with an n-type dopant at a higher concentration than a concentration of the buffer layer 121. When the buffer layer 121 is a p-type, the first type contact layer 165 may be doped with a p-type dopant at a higher concentration than that of the buffer layer 121. An electrode may be further formed on the first type contact layer 165. As another example, the first type contact layer 165 may be formed from an electrode material, for example, a metal having high conductivity or various conductive materials. A support layer 150 may be formed on the silicon substrate 110 in a region other than the laser element 120. In addition, a support structure 140 may be further formed on the support layer 150 on which the first type contact layer 165 is formed, and the first type contact layer 165 may be formed to extend with respect to the support structure 140.

The second type contact layer 160 may include the same material as the second type semiconductor layer 135 or the capping layer 137, and the second type contact layer 160 may be doped with a dopant at a higher concentration than a concentration of the second type semiconductor layer 135. When the second type semiconductor layer 135 is a p-type, the second type contact layer 160 may be doped with a p-type dopant at a higher concentration than a concentration of the second type semiconductor layer 135 or the capping layer 137. When the second type semiconductor layer 135 is an n-type, the second type contact layer 160 may be doped with an n-type dopant at a higher concentration than a concentration of the second type semiconductor layer 135 or the capping layer 137. An electrode may be further formed on the second type contact layer 160. As another example, the second type contact layer 160 may be formed from an electrode material, for example, a metal having high conductivity or various conductive materials.

The laser element 120 may further include a superlattice layer 122 between the buffer layer 121 and the first type semiconductor layer 125. The superlattice layer 122 may further reduce defects due to a lattice constant difference between silicon and a III-V compound semiconductor material during crystal growth, and may be based on the III-V compound semiconductor material. For example, when the buffer layer 121 includes n-GaAs, the superlattice layer 122 may be repeatedly stacked such that a GaAs layer and an AlAs layer form a superlattice.

In this way, the laser element 120 may be directly grown on the silicon substrate 110 on which the multi-groove pattern 111 is formed, and may emit the pump laser light La having a wavelength bandwidth. For example, the laser element 120 may directly contact the multi-groove pattern 111.

FIGS. 11 to 13 illustrate cross-sectional views of various structures of the laser element 120 according to embodiments. FIGS. 11 to 13 show the structures without the capping layer 137, but are not limited thereto. As shown in FIG. 2, the capping layer 137 may be provided on the light emitting layer structure 130.

The laser element 120 may further include a lattice structure 139, as shown in FIGS. 11 and 12. In addition, the silicon substrate 110 may include a SOI substrate, as shown in FIGS. 12 and 13.

The laser element 120 of FIG. 11 shows an example of the laser element 120 further including the lattice structure 139 compared to the laser element 120 of FIG. 2. FIG. 12 illustrates an example in which the laser element 120 further includes the lattice structure 139 compared to FIG. 2, and the silicon substrate 110 is the SOI substrate. The laser element 120 of FIG. 13 shows an example in which the silicon substrate 110 is the SOI substrate compared to FIG. 2. The SOI substrate may have a stacked structure of a first silicon layer 110a, an insulating layer 110b, and a second silicon layer 110c. The insulating layer 110b may be, for example, a SiO₂ layer.

Referring to FIGS. 11 and 12, the lattice structure 139 may be formed on one side or both sides of the light emitting layer structure 130. FIGS. 11 and 12 show an example in which the lattice structure 139 is formed on one side of the light emitting layer structure 130.

For example, the lattice structure 139 may be formed on one side or both sides of the light emitting layer structure 130 by patterning, while the second clad layer 133 and the second type semiconductor layer 135 formed on the quantum well structure 131 are stacked to a position where the lattice structure 139 is to be formed. As another example, the lattice structure 139 may be formed by forming a separate material layer at the position where the lattice structure 139 is to be formed, and patterning the material layer. In addition, an insulating layer or the like may be formed in a region other than the light emitting layer structure 130, and the lattice structure 139 may be formed on the insulating layer. The lattice structure 139 may be formed of a metallic material. For example, the lattice structure 139 may include gold (Au), titanium (Ti), silver (Ag), or platinum (Pt). However, embodiments are not limited thereto.

The lattice structure 139 may include a plurality of lattices periodically arranged. The wavelength of the pump laser light La emitted from the laser element 120 may be adjusted according to an arrangement period of the plurality of lattices of the lattice structure 139.

Referring back to FIG. 1, the waveguide 170 may have an input end formed to correspond to a light emission surface of the laser element 120. The waveguide 170 may be formed to be located approximately at a level of the quantum well structure 131 of the laser element 120. To this end, the support layer 150 may be formed on the silicon substrate 110 with an insulating material at an appropriate thickness in the vertical direction. The support layer 150 may include, for example, an oxide such as SiO₂, hafnium oxide (HfOₓ), aluminum oxide (Al₂O₃), etc. A separating distance between the input end of the waveguide 170 and the light emission surface of the laser element 120 may be determined so that the pump laser light La emitted from the laser element 120 may be coupled to the waveguide 170 at the maximum or at an appropriate ratio or more. The waveguide 170 may be formed of a material having relatively small light transmission loss with respect to a wavelength of the pump laser light La. For example, the waveguide 170 may be formed of silicon (Si), silicon nitride (Si₃N₄), etc.

The support layer 150 and the waveguide 170 formed thereon may be formed by, for example, a semiconductor manufacturing process after the laser element 120 is formed by direct growth on the silicon substrate 110. As a result, the formed multi-wavelength laser light source 100 may reduce alignment issues between the laser element 120 and the waveguide 170, and have improved yield, and accordingly have price competitiveness, and be miniaturized.

The support layer 150 may be formed on the silicon substrate 110 to enable other optical elements optically coupled to the waveguide 170 to be disposed. For example, the micro-resonator 180 may be formed on the support layer 150 to be optically coupled to the waveguide 170. The micro-resonator 180 may also be formed after the laser element 120 is formed. The support layer 150 may be formed on the silicon substrate 110, and then the waveguide 170 and the micro-resonator 180 may be formed on the support layer 150, but it is not limited thereto. For example, without the support layer 150, the waveguide 170 and the micro-resonator 180 may be directly formed on and may directly contact the silicon substrate 110. Here, an example in which the support layer 150 is formed on the silicon substrate 110 and the waveguide 170 and the micro-resonator 180 are formed on the support layer 150 is described.

The micro-resonator 180 may be formed on the silicon substrate 110 to enable optical coupling to the waveguide 170. When the support layer 150 is provided on the silicon substrate 110, the micro-resonator 180 may be formed on the support layer 150 of the silicon substrate 110. The micro-resonator 180 may be formed to have anomalous group velocity dispersion (GVD), that is, anomalous dispersion. Accordingly, a soliton frequency comb may be formed by a nonlinear effect with respect to the pump laser light La coupled from the waveguide 170 to the micro-resonator 180. Laser light Lc having a plurality of discontinuous wavelength bands of the soliton frequency comb generated by the micro-resonator 180, that is, the laser light Lc of a plurality of wavelengths, may be coupled from the micro-resonator 180 to the waveguide 170 and transmitted through the waveguide 170, but embodiments are not limited thereto. For example, the multi-wavelength laser light source 100 according to the embodiment may further include an additional waveguide that transmits the laser light Lc having the plurality of discontinuous wavelength bands of the soliton frequency comb generated by the micro-resonator 180. The additional waveguide may be formed on the silicon substrate 110 to enable optical coupling to the micro-resonator 180, and the laser light Lc may be transmitted through the additional waveguide. Hereinafter, an example in which the laser light Lc of the plurality of wavelengths is coupled from the micro-resonator 180 to the waveguide 170 and transmitted through the waveguide 170 will be described.

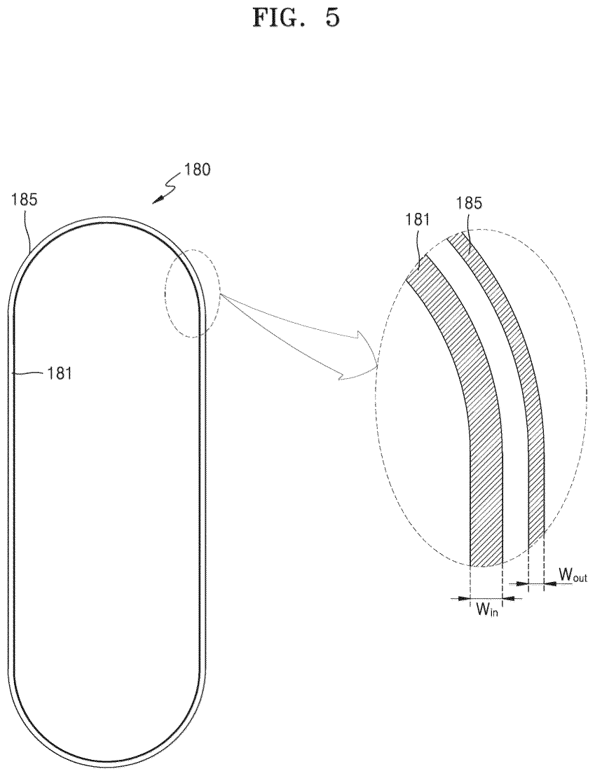

The micro-resonator 180 may be formed to have an anomalous dispersion mode even with a relatively thin thickness in the vertical direction. For example, as illustrated in FIGS. 1 and 5, the micro-resonator 180 may be formed in a racetrack concentric ring structure with a dual structure of an inner ring 181 and an outer ring 185, which are spaced apart from each other. When formed in such a racetrack concentric ring structure, the total length of the inner ring 181 may be less than the total length of the outer ring 185. At this time, the inner ring 181 and the outer ring 185 may have different cross-sectional widths in the horizontal direction in order to have anomalous dispersion characteristics in an anti-symmetric mode. By varying cross-sectional widths in the horizontal direction, the micro-resonator 180 may be formed such that an effective light path length of the inner ring 181 is the same as an effective light path length of the outer ring 185 by adjusting an effective refractive index of each of the inner ring 181 and the outer ring 185.

The effective refractive index may be adjusted corresponding to the width in the horizontal direction of the micro-resonator 180. For example, the effective refractive index of each of the inner ring 181 and the outer ring 185 may be adjusted corresponding to the cross-sectional width in the horizontal direction. When the cross-sectional width is relatively large, the effective refractive index may be relatively large, and when the cross-sectional width is relatively small, the effective refractive index may be relatively small. Therefore, although the total length of the inner ring 181 is less than the total length of the outer ring 185 due to the racetrack concentric ring structure with the dual structure, the effective refractive index of the inner ring 181 may be greater than the refractive index of the outer ring 185 so that the effective light path length of the inner ring 181 may be the same as the effective light path length of the outer ring 185. The inner ring 181 may be formed to have a cross-sectional width that is greater than the cross-sectional width of the outer ring 185 so that the effective refractive index of the inner ring 181 is greater than the effective refractive index of the outer ring 185. FIG. 4 illustrates a cross-sectional view of the micro-resonator 180 of FIG. 1. As illustrated in FIG. 4, for example, when a cross-sectional width of the inner ring 181 is Win, and a cross-sectional width of the outer ring 185 is Wout, Win>Wout may be satisfied. For example, the cross-sectional width of the inner ring 181 Win may be greater than a cross-sectional width of the outer ring 185 Wout. In addition, the inner ring 181 and the outer ring 185 may be formed to have the same thickness h in the vertical direction, but embodiments are not limited thereto. The inner ring 181 and the outer ring 185 may be formed to have a separation distance Wgap. In FIG. 4, Rin indicates the outermost radius of the inner ring 181, and Rout indicates the outermost radius of the outer ring 185.

The inner ring 181 and the outer ring 185 of the micro-resonator 180 may include the same material, but are not limited thereto. For example, the inner ring 181 and the outer ring 185 may be formed of different materials. In addition, the inner ring 181 and the outer ring 185 of the micro-resonator 180 may be formed of, for example, Si₃N₄. As another example, each of the inner ring 181 and the outer ring 185 of the micro-resonator 180 may include at least one of Silica, LiNbO₃, Ta₂O₅, Si, GaP, AlN, AlGaAs, InP, or TiO₂ each having a high nonlinear refractive index. However, embodiments are not limited thereto.

For example, each of the inner ring 181 and the outer ring 185 of the micro-resonator 180 may be formed of the same material as a material of the waveguide 170, but embodiments are not limited thereto. When each of the inner ring 181 and the outer ring 185 of the micro-resonator 180 is formed of the same material as that of the waveguide 170, the inner ring 181 and the outer ring 185 of the micro-resonator 180 and the waveguide 170 may be formed in the same process step at the same time or same period. As another example, when the inner ring 181 and the outer ring 185 of the micro-resonator 180 are formed of a material that is different from that of the waveguide 170, the inner ring 181 and the outer ring 185 of the micro-resonator 180 and the waveguide 170 may be formed in different process steps at different times or different periods.

For example, the micro-resonator 180 may be specialized in wavelength division multiplexing (WDM) and formed in the racetrack concentric ring structure with the dual structure of the inner ring 181 and the outer ring 185 to generate a soliton frequency comb in an O-band of relatively small dispersion, for example, a center wavelength 1,310 nm band. For example, the inner ring 181 and the outer ring 185 may be formed of silicon nitride (Si₃N₄), the separation distance between the inner ring 181 and the outer ring 185 may be Wgap=0.9 μm, the inner ring 181 may be formed in dimensions of the width Win=2.65 μm in the horizontal direction, the outermost radius of the racetrack concentric ring Rin=48.5 μm in the horizontal direction, and the thickness h=300 nm in the vertical direction, and the outer ring 185 may be formed in dimensions of the width Wout=1.2 μm in the horizontal direction, the outermost radius of the race track concentric ring Rout=50.6 μm in the horizontal direction, and the thickness h=300 nm in the vertical direction. However, embodiments are not limited thereto.

In this way, the micro-resonator 180 may be formed to have the anomalous dispersion characteristics in the racetrack concentric ring structure with the double structure of the inner ring 181 and the outer ring 185, which are spaced apart from each other, and thus the micro-resonator 180 may form a soliton and generate a stable soliton Kerr frequency comb.

The inner ring 181 and the outer ring 185 of the micro-resonator 180 are circular in FIG. 1, but are not limited thereto. As illustrated in FIG. 5, the inner ring 181 and the outer ring 185 may be formed in the racetrack concentric ring structure having, for example, an oblong shape so that the effective light path length of the inner ring 181 is the same as the effective light path length of the outer ring 185, but may also be formed in various shapes. For example, as shown in FIG. 5, the micro-resonator 180 is in the racetrack concentric ring structure having the oblong shape in which the dual structure of the inner ring 181 and the outer ring 185 has a straight portion, and the oblong shape may be formed to include curved track portions and straight track portions. In this case, an effective light path length OPLin of the inner ring 181 may be the sum of an effective light path length OPLin^{st} of the straight track portions and an effective light path length OPLin^{bent} of the curved track portions, for example, OPLin=OPLin^{st}+OPLin^{bent}. An effective light path length OPLout of the outer ring 185 may be the sum of an effective light path length OPLout^{st} of the straight track portions and an effective light path length OPLout^{bent} of the curved track portions, that is, OPLout=OPLout^{st}+OPLout^{bent}. Because lengths of the straight track portions of the inner ring 181 and the outer ring 185 are the same, when the curved track portions at both ends of the straight track portions correspond to, for example, semicircles, OPLin=OPLin^{st}+OPLin^{bent}=2Lₛₜhᵢₙ+2πRᵢₙnᵢₙ, and OPLout=OPLout^{st}+OPLout^{bent}=2Lₛₜnₒᵤₜ+2πRₒᵤₜhₒᵤₜ. Here, Lₛₜ indicates a length of the straight track portion of each of the inner ring 181 and the outer ring 185, Rᵢₙ indicates a radius of the curved track portion of the inner ring 181, nᵢₙ indicates an effective refractive index of the inner ring 181, Rₒᵤₜ indicates a radius of the curved track portion of the outer ring 185, and nₒᵤₜ indicates an effective refractive index of the outer ring 185. The effective refractive index nᵢₙ of the inner ring 181 may vary depending on the width Win of the inner ring 181, and the effective refractive index nₒᵤₜ of the outer ring 185 may vary depending on the width Wout of the outer ring 185. By setting the length of the straight track portion, the radius of the curved track portion, and the width of each of the inner ring 181 and the outer ring 185, the micro-resonator 180 may be formed such that the effective light path length OPLin of the inner ring 181 is the same as the effective light path length OPLout of the outer ring 185. For example, the inner ring 181 and the outer ring 185 of the micro-resonator 180 may be formed to satisfy the condition of OPLin=OPLout.

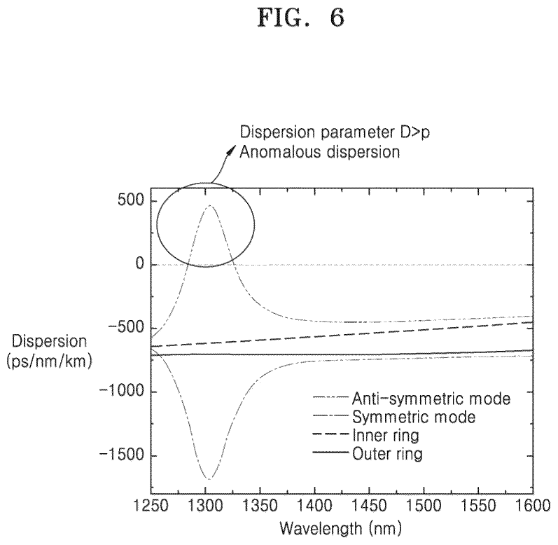

FIG. 6 shows anomalous dispersion characteristics of the micro-resonator 180 formed in an anti-symmetric mode. FIG. 6 shows simulation results that there may be a mode with anomalous dispersion in an O-band (a center wavelength 1,310 nm band) when the micro-resonator 180 of the embodiment is formed from Si₃N₄ and is formed in a racetrack concentric ring structure.

As may be seen from FIG. 6, because the inner ring 181 and the outer ring 185 of the micro-resonator 180 of one or more embodiments have different cross-sectional widths in the horizontal direction, the inner ring 181 and the outer ring 185 may have different dispersion characteristics, such that due to a dual structure of the inner ring 181 and the outer ring 185, the micro-resonator 180 of the embodiment may have the anomalous dispersion characteristics in the anti-symmetric mode. In FIG. 6, a symmetric mode relates to a micro-resonator of a related example having a single ring structure with normal dispersion characteristics. For example, Si₃N₄ material may have normal dispersion characteristics, and thus for example, a non-solitonic frequency comb may be formed at a thickness in the vertical direction compatible with a CMOS process. The micro-resonator 180 of one or more embodiments has the racetrack concentric ring structure with the dual structure of the inner ring 181 and the outer ring 185, thereby forming the anti-symmetric mode that exhibits the anomalous dispersion characteristics even at a relatively thin thickness in the vertical direction. In such anomalous dispersion, a soliton may be formed, resulting in a very stable soliton Kerr frequency comb.

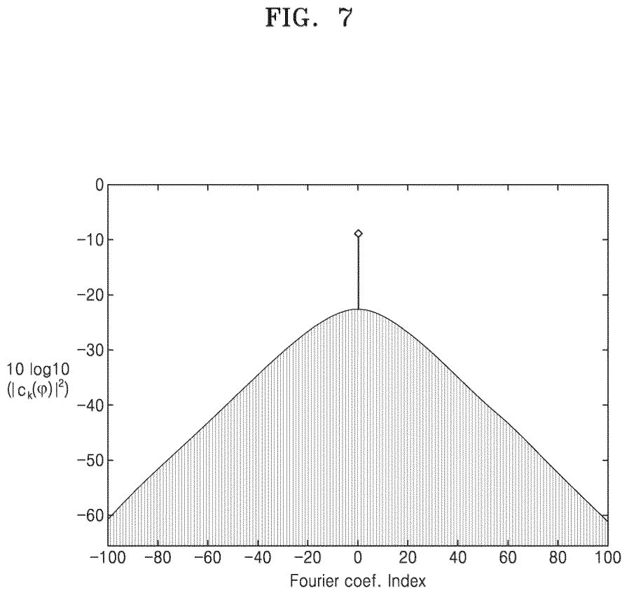

FIG. 7 shows a soliton frequency comb generated with respect to the pump laser light La in a wavelength band having anomalous dispersion. In the graph of FIG. 7, a horizontal axis represents an angular frequency ω of a soliton frequency comb with respect to a center wavelength of a pump laser light La, and a vertical axis represents power of the soliton frequency comb. Frequency 0 on the horizontal axis corresponds to the angular frequency ω of the center wavelength of the pump laser light La. As shown in FIG. 7, the soliton frequency comb generated by the micro-resonator 180 of one or more embodiments may have a Sech² envelope shape during stability, and thus a stable multi-wavelength laser light source that generates a laser light Lc of a plurality of wavelengths may be obtained and utilized as a light source suitable for WDM.

In the micro-resonator 180, a total dispersion is the net effect of material dispersion and geometric dispersion, and the material dispersion is due to a change in the refractive index according to a wavelength. The geometric dispersion is due to a variation in the effective refractive index because of a change in the shape of a light mode according to a wavelength. Most of materials and wavelengths exhibit normal dispersion. Even when the micro-resonator 180 of one or more embodiments includes a material having normal dispersion characteristics, the micro-resonator 180 of one or more embodiments may implement anomalous dispersion through a geometric structure adjustment.

A dispersion D is related to a wavelength λ and a refractive index n of a material as shown in Equation 1 below.

$$D = - \frac{λ}{c} \frac{{d}^{2} n}{d {λ}^{2}} \qquad 〈 Equation 1 〉$$

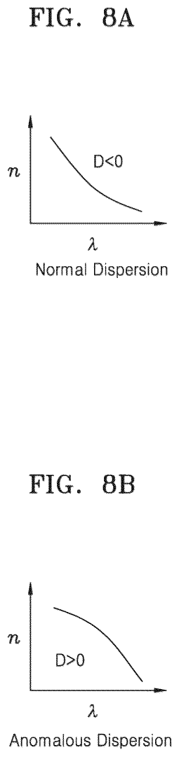

When the dispersion is negative, i.e., D<0, the dispersion is referred to as normal dispersion, and when the dispersion is positive, i.e., D>0, the dispersion is referred to as anomalous dispersion. FIG. 8A illustrates a change in a refractive index according to a wavelength in the normal dispersion (D<0). FIG. 8B illustrates a change in a refractive index according to a wavelength in the anomalous dispersion (D>0).

Each of the inner ring 181 and the outer ring 185 of the micro-resonator 180 of one or more embodiments may be formed of a material having normal dispersion characteristics, such as Si₃N₄, as shown in FIG. 8A. The micro-resonator 180 of one or more embodiments may have the anomalous dispersion characteristics by adjusting a geometric structure of the racetrack concentric ring structure with the dual structure of the inner ring 181 and the outer ring 185, and thus have an anomalous GVD, such that the micro-resonator 180 of one or more embodiments may form an anti-symmetric mode indicating the anomalous dispersion characteristics.

In addition, when each of the inner ring 181 and the outer ring 185 of the micro-resonator 180 of one or more embodiments is formed from a material having the anomalous dispersion characteristics as shown in FIG. 8B, the micro-resonator 180 may have anomalous dispersion characteristics of the material and the anomalous dispersion characteristics by adjusting the geometric structure of the racetrack concentric ring structure with the dual structure of the inner ring 181 and the outer ring 185, and thus have the anomalous GVD, such that the micro-resonator 180 of one or more embodiments may form the anti-symmetric mode indicating the anomalous dispersion characteristics.

As described above, the multi-wavelength laser light source 100 according to one or more embodiments may form the soliton frequency comb based on the nonlinear effect with respect to the pump laser light La emitted from the laser element 120 directly grown on the silicon substrate 110 on which the multi-groove pattern 111 is formed and transferred through the waveguide 170 by using the micro-resonator 180 of the racetrack concentric ring structure of with dual structure of the inner ring 181 and the outer ring 185 and generate the laser light Lc having a plurality of discontinuous wavelength bands, that is, the laser light Lc of the plurality of wavelengths.

An example in which the micro-resonator 180 is provided in the racetrack concentric ring structure with the dual structure of the inner ring 181 and the outer ring 185 to have the anomalous dispersion characteristics through geometric structure adjustment is explained, but embodiments are not limited thereto. For example, the micro-resonator 180 may include a micro-disk, a micro-sphere, a micro-toroid, a micro-ring, etc. provided to have the anomalous dispersion characteristics through geometric structure adjustment.

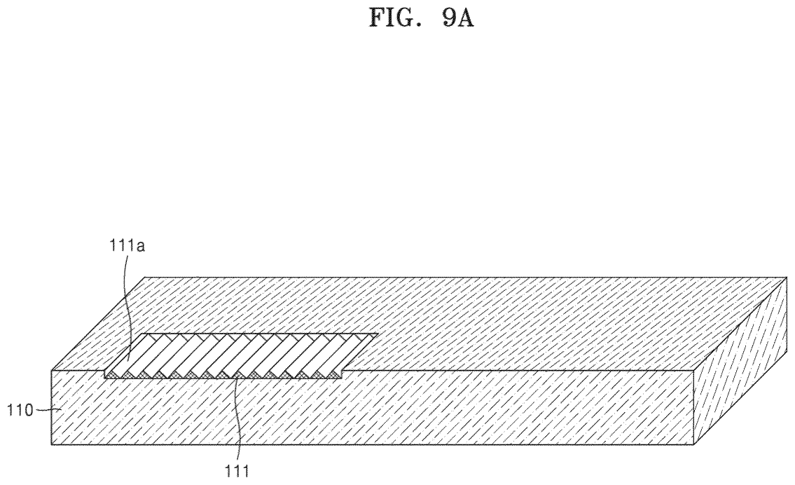

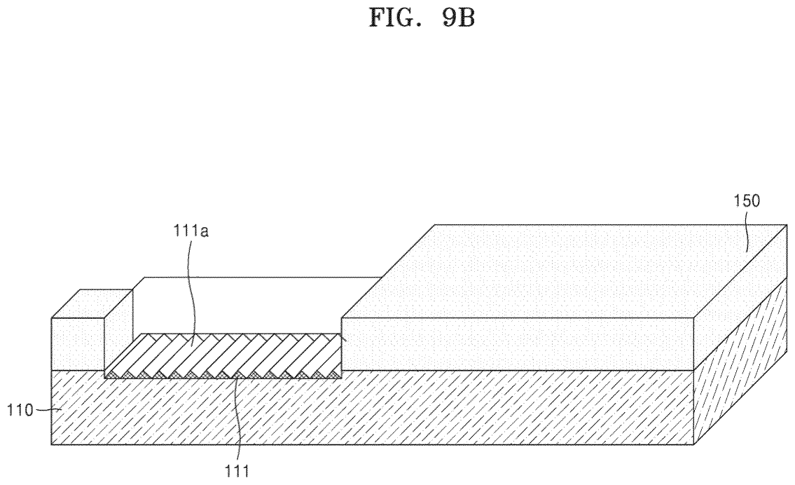

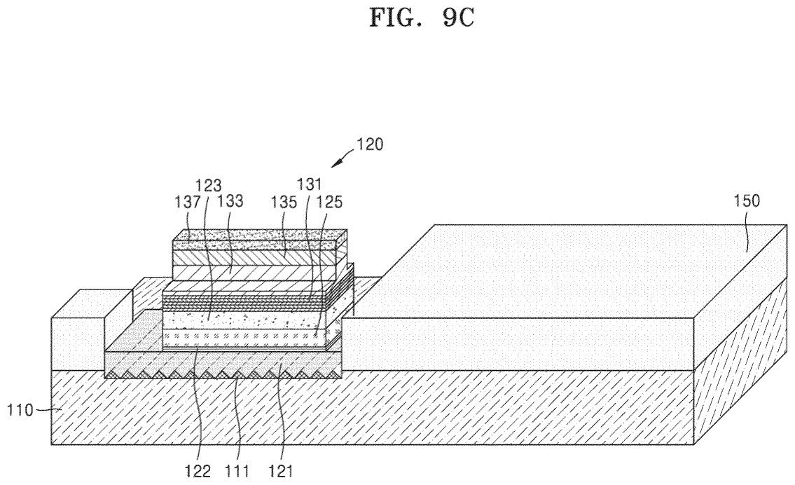

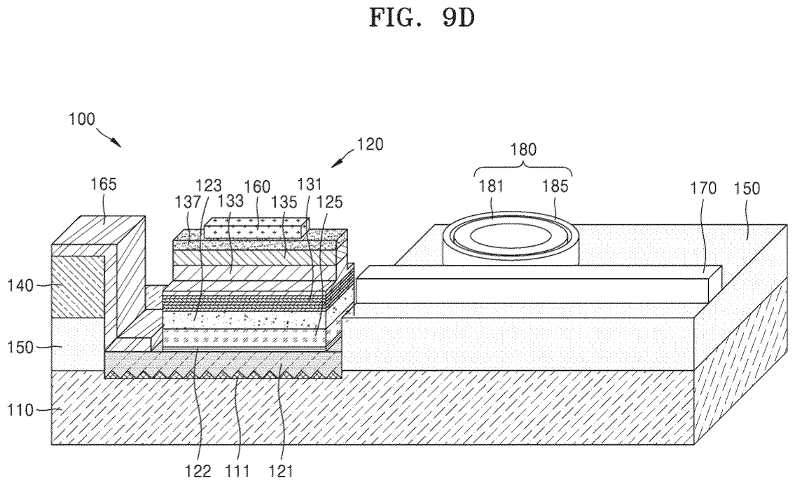

FIGS. 9A to 9D schematically show a method of manufacturing a multi-wavelength laser light source 100 according to one or more embodiments. FIGS. 9A to 9D merely show an example of the method of manufacturing the multi-wavelength laser light source 100 according to one or more embodiments, but are not limited thereto.

Referring to FIG. 9A, a multi-groove pattern 111 may be formed in a partial region of the silicon substrate 110. The multi-groove pattern 111 may be formed by etching, for example, wet etching a silicon substrate 110. The multi-groove pattern 111 may be formed in the shape of a multi-V groove, as described above with reference to FIG. 3. The multi-groove pattern 111 may include a silicon material. The multi-groove pattern 111 in the shape of the multi-V groove may be formed by, for example, wet etching. Wet etching may be performed, for example, using a KOH or TMAH solution as an etching medium. The multi-groove pattern 111 may form a multi-Si (111) surface 111a. With respect to the multi-Si (111) surface 111a, as shown in FIG. 9C, a compound semiconductor material with a relatively large lattice constant difference from silicon, such as a III-V compound semiconductor material, may be crystal-grown.

Referring to FIG. 9B, a support layer 150 including an insulating material may be formed at an appropriate thickness in the vertical direction on the silicon substrate 110 other than a region in which a laser element 120 is to be formed. The support layer 150 may be formed on the silicon substrate 110 to enable a waveguide 170 to be located at a level of a quantum well structure 131 of the laser element 120 in a subsequent process, and another optical element, for example, a micro-resonator 180, which is optically coupled to the waveguide 170 to be disposed. The support layer 150 may also be formed after a process of forming the laser element 120, as shown in FIG. 9C. The support layer 150 may include, for example, an oxide such as SiO₂, HfOₓ, Al₂O₃, etc. The support layer 150 may be formed on the silicon substrate 110 by a deposition process.

Next, as shown in FIG. 9C, the laser element 120 that is based on and include a III-V compound semiconductor material by direct growth on the silicon substrate 110 and generates a pump laser light La may be formed. For example, a buffer layer 121 may be formed by crystal growth with respect to the multi-groove pattern 111, and a light emitting layer structure 130 (referring to FIG. 2) including the quantum well structure 131 formed by alternately stacking quantum barrier layers 131a (referring to FIG. 2) and quantum well layers 131b (referring to FIG. 2) on the buffer layer 121 by epitaxial growth may be formed. Thereafter, an electrical contact structure with respect to the laser element 120 may be formed. The electrical contact structure with respect to the laser element 120 may be formed before or after the formation of the waveguide 170 and the micro-resonator 180.

To form the laser element 120, first, the buffer layer 121 may be crystal-grown with respect to the multi-groove pattern 111. The buffer layer 121 may be formed to fill the multi-V groove and be formed to a height greater than or equal to the multi-V groove. For example, an ART layer 121a (referring to FIG. 3) filling the multi-V groove may be formed, and a NRE layer 121b (referring to FIG. 3) formed by crystal growth of the ART layer 121a may be formed. The ART layer 121a may correspond to a portion of the buffer layer 121 formed to fill the multi-V groove, and the NRE layer 121b may correspond to a portion of the buffer layer 121 formed to a certain thickness in the vertical direction after filling the multi-V groove.

The ART layer 121a and the NRE layer 121b may be formed from a compound semiconductor material in which at least one element is different, or may include the same compound semiconductor material. When the ART layer 121a and the NRE layer 121b are formed from the same compound semiconductor material, the ART layer 121a and the NRE layer 121b may be continuously formed without an interlayer interface. When the ART layer 121a and the NRE layer 121b are formed from the compound semiconductor materials in which at least one element is different, the ART layer 121a and the NRE layer 121b may be continuously formed without an interlayer interface or an interlayer interface may be formed therebetween. At this time, the ART layer 121a and the NRE layer 121b may include a III-V compound semiconductor material, for example, a compound semiconductor material including at least two of indium (In), gallium (Ga), aluminum (Al), arsenic (As), or phosphorus (P). As another example, the ART layer 121a and the NRE layer 121b may include a multilayer structure of a compound semiconductor material including at least two of indium (In), gallium (Ga), aluminum (Al), arsenic (As), or phosphorus (P). The ART layer 121a and the NRE layer 121b may include, for example, GaAs, InGaAs, or InP. However, embodiments are not limited thereto. The ART layer 121a may include, for example, GaAs. The NRE layer 121b may include, for example, InGaAs, for example, In_{0.25}GaAs. As another example, the ART layer 121a and the NRE layer 121b may include GaAs.

The light emitting layer structure 130 including the quantum well structure 131 may be epitaxially grown on the buffer layer 121 formed as described above. The quantum well structure 131 of the light emitting layer structure 130 may be formed by two or more alternate growths of the quantum barrier layer 131a of about 3 nm or more and the quantum well layer 131b of about 3 nm or more. Each of the quantum barrier layers 131a may be formed to a thickness in the vertical direction of about 3 nm or more, for example, about 3 nm or more and 50 nm or less, and each of the quantum well layers 131b may be formed to a thickness in the vertical direction of about 3 nm or more, for example, about 3 nm or more and 25 nm or less. However, embodiments are not limited thereto, and the quantum barrier layer 131a and the quantum well layer 131b may also be formed to have various thicknesses in the vertical direction. Each of the quantum barrier layer 131a and the quantum well layer 131b may independently include at least one of In, Ga, Al, As, P, Si, Zn, or C. For example, the quantum barrier layer 131a may include InₓGa_{y}Al_{z}As (0.00≤x≤0.50, 0.00≤y, z≤0.95), and the quantum well layer 131b may include InₓGa_{y}Al_{z}As (0.20≤x≤0.60, 0.00≤y, z≤0.95). For example, the quantum well layer 131b may include phosphorus (In), and the content of phosphorus (In) may be in a range of about 0.20 to about 0.55, for example, about 0.45. The quantum barrier layer 131a may selectively include phosphorus (In), and the content of phosphorus (In) may be in a range of about 0.00 to about 0.45, for example, about 0.25. As an example, the quantum well structure 131 may be formed by two or more alternate growths of the quantum barrier layer 131a including GaAs and the quantum well layer 131b including InGaAs, for example, In_{0.45}GaAs.

The emission wavelength band of the quantum well structure 131 may be adjusted by changing at least one of the shape, material, and thickness in the vertical direction of the quantum well layer 131b, and the emission intensity may be adjusted by changing the number of layers of the quantum well layer 131b. The quantum well structure 131 may be formed to generate light in a wavelength range of about 950 nm or more and about 1,750 nm or less. For example, the quantum well structure 131 may be formed to generate the pump laser light La having a center wavelength of approximately 1,310 nm and a certain wavelength bandwidth.

At least one of a first type semiconductor layer 125 and a first clad layer 123 may be further formed between the buffer layer 121 and the quantum well structure 131. In addition, at least one of a second clad layer 133 and a second type semiconductor layer 135 may be further formed on the quantum well structure 131. For example, the first type semiconductor layer 125, the first clad layer 123, the quantum well structure 131, the second clad layer 133, and the second type semiconductor layer 135 may be sequentially stacked on the NRE layer 121b of the buffer layer 121. The light emitting layer structure 130 formed as described above may be substantially the same as the light emitting layer structure 130 described above with reference to FIGS. 2 and 11 to 13.

A capping layer 137 may be formed on the light emitting layer structure 130. The capping layer 137 may be formed to be adjacent to and surround the buffer layer 121 and the light emitting layer structure 130 protruding above the support layer 150. As another example, the capping layer 137 may be formed to be adjacent to and surround only the light emitting layer structure 130. The capping layer 137 may include a material including a certain dopant. The capping layer 137 may include, for example, a material including a certain dopant in InGaP. The capping layer 137 may be substantially the same as the capping layer 137 described with reference to FIG. 2.

Referring to FIG. 9D, an electrical contact with respect to the laser element 120 may be formed, and a micro-resonator 180 and a waveguide 170 may be formed on the silicon substrate 110.

To form the electrical contact with respect to the laser element 120, for example, a first type contact layer 165 may be formed in a region on the buffer layer 121, and a second type contact layer 160 may be formed on the second type semiconductor layer 135. A support structure 140 may be further formed on the support layer 150 on which the first type contact layer 165 is formed, and the first type contact layer 165 may be formed to extend with respect to the support structure 140. The first type contact layer 165 may be formed to be in contact with the silicon substrate 110. When the capping layer 137 is formed on the second type semiconductor layer 135, the second type contact layer 160 may be formed on the capping layer 137. The first type contact layer 165 and the second type contact layer 160 may be substantially the same as the first type contact layer 165 and the second type contact layer 160 described with reference to FIG. 2, respectively. An electrode may be further formed on the first type contact layer 165 and the second type contact layer 160. The entire process or at least some process of forming the electrical contact with respect to the laser element 120 may be formed after the formation of the micro-resonator 180 and the waveguide 170.

The micro-resonator 180 may be formed to have an anomalous GVD. The waveguide 170 may be formed to have an input end located at a level of the quantum well structure 131 of the laser element 120. In addition, the micro-resonator 180 and the waveguide 170 may be formed to be optically coupled. When the support layer 150 is formed on the silicon substrate 110, the micro-resonator 180 and the waveguide 170 may be formed on the support layer 150. The micro-resonator 180 may be formed to have the anomalous GVD, and thus the pump laser light La may be coupled to generate a laser light Lc having a plurality of discontinuous wavelength bands of a soliton frequency comb by a nonlinear effect. The anomalous dispersion characteristics of the micro-resonator 180 may be implemented by geometric dispersion through geometric structure adjustment. In addition, the anomalous dispersion characteristics of the micro-resonator 180 may be implemented by material dispersion. In addition, the anomalous dispersion characteristics of the micro-resonator 180 may be implemented by a combination of geometric dispersion and material dispersion. Hereinafter, an example in which the anomalous dispersion characteristics of the micro-resonator 180 are implemented by geometric dispersion will be mainly described.

The micro-resonator 180 may be formed in a racetrack concentric ring structure with a dual structure of an inner ring 181 and an outer ring 185, which are spaced apart from each other. The inner ring 181 and the outer ring 185 may be formed to have different cross-sectional widths in the horizontal direction, in order to have the anomalous dispersion characteristics in an anti-symmetric mode. By making cross-sectional widths different, the micro-resonator 180 may be formed such that an effective light path length of the inner ring 181 is the same as an effective light path length of the outer ring 185 by adjusting effective refractive indices of the inner ring 181 and the outer ring 185. For example, when a cross-sectional width of the inner ring 181 is Win, and a cross-sectional width of the outer ring 185 is Wout, it may be Win>Wout. In addition, the inner ring 181 and the outer ring 185 may be formed to have, for example, the same thickness h in the vertical direction, but are not limited thereto.

The inner ring 181 and the outer ring 185 of the micro-resonator 180 may be formed from the same material, but are not limited thereto. For example, the inner ring 181 and the outer ring 185 may also be formed from different materials. In addition, the inner ring 181 and the outer ring 185 of the micro-resonator 180 may be formed from, for example, Si₃N₄. As another example, each of the inner ring 181 and the outer ring 185 of the micro-resonator 180 may include at least one of Silica, LiNbO₃, Ta₂O₅, Si, GaP, AlN, AlGaAs, InP, or TiO₂ having a relatively high nonlinear refractive index. However, embodiments not limited thereto.

The waveguide 170 may be formed from a material having relatively small light transmission loss with respect to a wavelength of the pump laser light La. For example, the waveguide 170 may be formed from silicon (Si), silicon nitride (Si₃N₄), etc.

For example, each of the inner ring 181 and the outer ring 185 of the micro-resonator 180 may be formed from the same material as a material of the waveguide 170, but embodiments are not limited thereto. The inner ring 181 and the outer ring 185 of the micro-resonator 180 may be formed from the same material as a material of the waveguide 170, and the inner ring 181 and the outer ring 185 of the micro-resonator 180 and the waveguide 170 may be formed in the same process step at the same time or same period. As another example, the inner ring 181 and the outer ring 185 of the micro-resonator 180 may be formed from a material that is different from that of the waveguide 170, and the inner ring 181 and the outer ring 185 of the micro-resonator 180 and the waveguide 170 may be formed in different process steps at different times or periods.

Referring to FIGS. 9C and 9D, it has been described that the laser element 120 is formed on the multi-groove pattern 111 of the silicon substrate 110, and then the micro-resonator 180 and the waveguide 170 are formed, but embodiments are not limited thereto. For example, the micro-resonator 180 and the waveguide 170 may be formed on the support layer 150, and then the laser element 120 may be formed on the multi-groove pattern 111 of the silicon substrate 110.

In addition, the multi-groove pattern 111 may be formed after forming the support layer 150 on the silicon substrate 110, or may be formed by forming the micro-resonator 180 and the waveguide 170 on the support layer 150 and then etching, for example, wet etching, the silicon substrate 110.

As described with reference to FIGS. 9A to 9D, the support layer 150 and the waveguide 170 formed thereon may be formed after the laser element 120 is formed by direct growth on the silicon substrate 110. Accordingly, the formed multi-wavelength laser light source 100 may reduce alignment issues between the laser element 120 and the waveguide 170.

FIGS. 9A to 9D show an example in which the laser element 120 is formed in the structure of FIG. 2, and the laser element 120 may be formed on an SOI substrate, and/or may be formed in a structure further including the lattice structure 139, as described with reference to FIGS. 11 to 13.

The laser element 120, the waveguide 170, and the micro-resonator 180 constituting the multi-wavelength laser light source 100 according to one or more embodiments described above may be formed on the silicon substrate 110 through a manufacturing process. The multi-wavelength laser light source 100 according to one or more embodiments may be implemented, for example, in the form of a single chip. In addition, a silicon PIC apparatus including the multi-wavelength laser light source 100 according to one or more embodiments may be implemented in the form of, for example, a single chip.

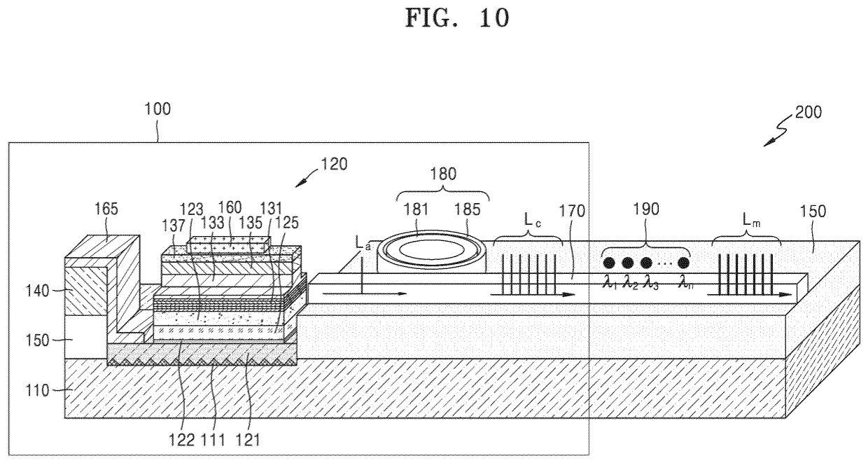

FIG. 10 is a schematically perspective view of a silicon PIC apparatus 200 including a multi-wavelength laser light source 100 according to one or more embodiments. FIG. 10 shows an example of applying the laser element 120 of FIG. 2, but embodiments are not limited thereto. The laser element 120 may have the structure shown in FIGS. 11 to 13.

Referring to FIG. 10, the silicon PIC apparatus 200 may include the multi-wavelength laser light source 100 formed on a silicon substrate 110 and at least one optical element provided on the silicon substrate 110 and optically connected to the multi-wavelength laser light source 100.

The multi-wavelength laser light source 100 may include the laser element 120 that generates the pump laser light La, a micro-resonator 180 that is coupled to the pump laser light La to form a soliton frequency comb and generates the laser light Lc having a plurality of discontinuous wavelength bands, and a waveguide 170 that transfers the pump laser light La to the micro-resonator 180. The multi-wavelength laser light source 100 including the laser element 120, the micro-resonator 180, and the waveguide 170 is the same as described with reference to FIG. 1, and redundant descriptions thereof are omitted here.

At least one optical element may include at least one light modulator, for example, a plurality of light modulators 190, modulating at least a part of the soliton frequency comb of the laser light Lc of the plurality of wavelengths traveling through the waveguide 170.

For example, the plurality of light modulators 190 may include, for example, first to nth light modulators to respectively modulate soliton frequencies of first to nth wavelength bands of the laser light Lc having the soliton frequency comb, where n may be an integer of 4 or more. In FIG. 10, λ1, λ2, λ3, . . . , λn may indicate center wavelengths of the first to nth wavelength bands at which the soliton frequencies are modulated. Laser light components of the first to nth wavelength bands having the soliton frequencies respectively modulated by the plurality of light modulators 190 may be coupled from the respective light modulators 190 to the waveguide 170, and a laser light Lm having a plurality of discontinuous wavelength bands of the modulated soliton frequency comb may be transmitted through the waveguide 170.

The plurality of light modulators 190 may be, for example, a single ring resonator array, and may be directly formed on the silicon substrate 110. For example, the plurality of light modulators 190 may directly contact the silicon substrate 110. Each of the plurality of light modulators 190 may be provided to modulate the laser light Lc of each of the wavelength bands. Each of the plurality of light modulators 190 may be formed on the silicon substrate 110 to be optically coupled to the waveguide 170, but embodiments are not limited thereto. Accordingly, the light component of each of the wavelength bands of the laser light Lc of the soliton frequency comb transmitted through the waveguide 170 may be coupled to each corresponding light modulator 190, modulated in the light modulator 190, and coupled again to the waveguide 170. Accordingly, the laser light Lm having the plurality of wavelength bands of the modulated soliton frequency comb may be transmitted through the waveguide 170. Here, a plurality of modulated wavelength bands may be discontinuous, or at least some of modulated wavelength bands may be discontinuous and the remaining modulated wavelength bands may be continuous. As another example, an additional waveguide transmitting the laser light Lm having the plurality of wavelength bands of the soliton frequency comb modulated by each of the plurality of light modulator 190 may be further included, and each of the plurality of light modulators 190 may be formed on the silicon substrate 110 to be optically coupled to the additional waveguide. The additional waveguide may include a single waveguide or a plurality of waveguides optically coupled to the plurality of light modulators 190, respectively.

The multi-wavelength laser light source 100 including the laser element 120, the waveguide 170, and the micro-resonator 180 and the plurality of light modulators 190 configuring the silicon PIC apparatus 200 according to one or more embodiments described above may be formed on the silicon substrate 110 by a manufacturing process. The silicon PIC apparatus 200 including the multi-wavelength laser light source 100 according to one or more embodiments may be implemented in the form of, for example, a single chip.

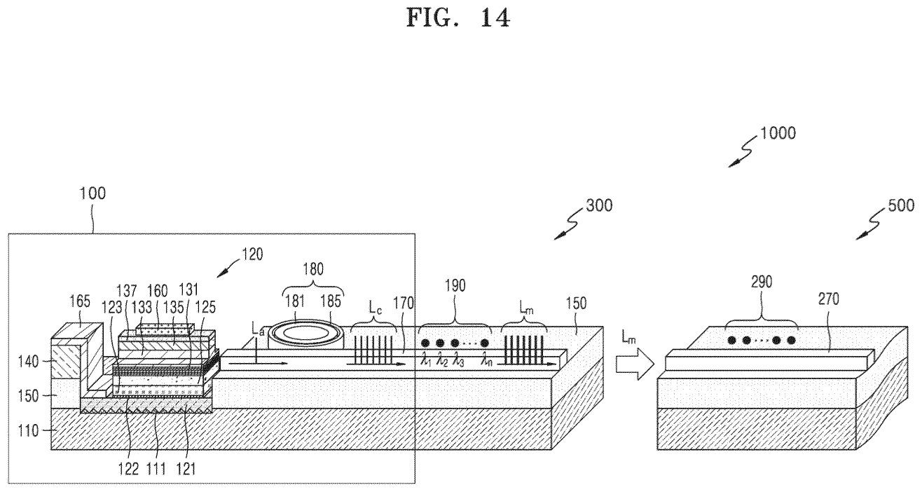

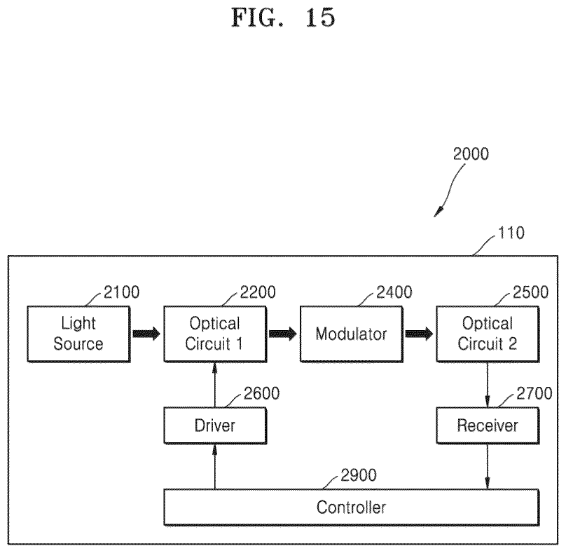

FIG. 14 shows a silicon PIC apparatus 1000 with a multi-wavelength laser light source 100 applied according to one or more embodiments.

Referring to FIG. 14, the silicon PIC apparatus 1000 includes a transmitter 300 including the multi-wavelength laser light source 100 and transmitting a laser light Lm of a plurality of wavelengths of a modulated soliton frequency comb, and a receiver 500 receiving the laser light Lm of the plurality of wavelengths of the modulated soliton frequency comb transmitted from the transmitter 300. FIG. 14 shows an example in which the transmitter 300 corresponds to the silicon PIC apparatus 200 including the multi-wavelength laser light source 100 of FIG. 10. An example in which the transmitter 300 transmits the laser light Lm of the plurality of wavelengths of the modulated soliton frequency comb is described, but is not limited thereto. For example, the transmitter 300 may correspond to the multi-wavelength laser light source 100 that provides a laser light Lc of a plurality of wavelengths of a soliton frequency comb of FIG. 1. In this case, the transmitter 300 may transmit the laser light Lc of the plurality of wavelengths of the soliton frequency comb.

The receiver 500 may include a waveguide 270 and a plurality of optical circuit elements 290 optically connected to the waveguide 270. Each of the plurality of optical circuit elements 290 may be provided to detect, for example, a laser light component of each wavelength band of the plurality of wavelengths of the laser light Lm of the modulated soliton frequency comb. For example, each of the plurality of optical circuit elements 290 may include a ring resonator to which the laser light component of each wavelength band of the plurality of wavelengths of the laser light Lm is coupled, a coupling element, for example, a waveguide, optically coupled to the ring resonator, and a photodetector that detects the laser light component of each wavelength band transferred through the coupling element.

FIG. 14 shows an example that the waveguide 170 of the multi-wavelength laser light source 100 and the waveguide 270 of the receiver 500 are separated to express the laser light Lm of the plurality of wavelengths emitted from the transmitter 300 including the multi-wavelength laser light source 100, and the waveguide 270 may have a structure extending from the waveguide 170.

For example, the waveguide 270 of the receiver 500 may be formed when the waveguide 170 is formed on the support layer 150 formed on the silicon substrate 110. The plurality of optical circuit elements 290 may also be formed on the support layer 150.

The multi-wavelength laser light source 100 according to one or more embodiments and the silicon PIC apparatus 1000 with the same applied may be applied to a light interconnection structure for relatively high-speed and large-capacity data transmission, thereby implementing a structure in which optical elements such as a light source and a transmission line are integrated on a single substrate.

In addition, the multi-wavelength laser light source 100 according to one or more embodiments and the silicon PIC apparatus 1000 with the same applied may be applied to a PIC that transmits a relatively large amount of light signals by using WDM.

The laser light Lm of the plurality of wavelengths emitted from the transmitter 300 may be emitted to an object, reflected or scattered from the object, and then may be input to the waveguide 270 of the receiver 500. The silicon PIC apparatus 1000 may be implemented as various devices such as a light detection and ranging (LiDAR), a spectral apparatus, etc. In this case, the arrangement of the receiver 500 may be different from that of FIG. 14. For example, the receiver 500 may be disposed so that an input end of the waveguide 270 does not face an output end of the waveguide 170 of the transmitter 300. The silicon substrate 110 on which the transmitter 300 and the receiver 500 are formed may be a single substrate or a separate substrate.

FIG. 15 is a block diagram of a schematic configuration of an optoelectronic apparatus 2000 according to one or more embodiments. The optoelectronic apparatus 2000 of FIG. 15 may include a silicon PIC apparatus and may constitute a light computing system, and may be, for example, a partial component included in an AI accelerator.

Referring to FIG. 15, the optoelectronic apparatus 2000 may include a silicon substrate 110, a light source 2100 provided in the silicon substrate 110, a light modulator 2400 that outputs a determination signal determined according to the form in which light is input from the light source 2100, and a controller 2900 that adjusts an input signal to the light modulator 2400 and processes an output from the light modulator 2400.

The light source 2100 may emit, for example, laser light in an infrared wavelength band. The light source 2100 may include any one of a multi-wavelength laser light source 100 according to one or more embodiments described above, a silicon PIC apparatus 200 including the same, or a transmitter 300 of a silicon PIC apparatus 1000 including the same. For example, the light source 2100 may output laser light having a plurality of discontinuous wavelength bands of a soliton frequency comb or a modulated soliton frequency comb within a range of about 950 nm to about 1,750 nm.

The light modulator 2400 may control an output light by modulating an incident light. The output light may be controlled to be on/off, or on/off may be defined according to the intensity of the output light. The light modulator 2400 may be provided to modulate, for example, light in an infrared wavelength band. For example, a light modulation layer of the light modulator 2400 may include a quantum well structure 131 including InGaAsP. Light of a specific wavelength band may transmit the light modulation layer or at least partially be absorbed from the light modulation layer according to whether a voltage is applied to the light modulator 2400. The light modulator 2400 may have, for example, a structure directly grown on and contacting the silicon substrate 110. As another example, the light modulator 2400 may be separately formed and integrated on the silicon substrate 110. The light modulator 2400 may be provided in a plurality of arrays.

The optoelectronic apparatus 2000 may further include an optical circuit provided to be optically connected to an output end or an input end of the light modulator 2400. For example, a first optical circuit 2200 may be provided between the light source 2100 and the light modulator 2400, and a driver 2600 may be controlled by a controller 2900, and may apply a control signal to the first optical circuit 2200. In addition, a second optical circuit 2500 may be provided in the output end of the light modulator 2400, and a signal of the second optical circuit 2500 may be transmitted to the controller 2900 through a receiver 2700. The first optical circuit 220, the light modulator 2400, and the second optical circuit 2500 may be a part of an optical transmission system.

The first optical circuit 2200 may have a configuration of modulating and branching light from the light source 2100. For example, the first optical circuit 2200 may have a configuration of modulating and branching light from the light source 2100 into the number and intensity of light required for input of the light modulator 2400, and may include a waveguide structure including one or more light splitters and one or more phase delayers.

The second optical circuit 2500 may convert the output light from the light modulator 2400 into an electrical signal. The second optical circuit 2500 may also amplify the output light emitted from the light modulator 2400 and convert the amplified output light into the electrical signal.

The multi-wavelength laser light source 100 according to one or more embodiments described above and the laser element 120 of the silicon PIC apparatuses 200 and 1000 including the same may be directly grown on and contacting the silicon substrate 110, and a relatively small low-power multi-wavelength laser light source, a silicon PIC apparatus including the same, and an optoelectronic apparatus with the same applied may be implemented. The multi-wavelength laser light source 100 according to one or more embodiments and the silicon PIC apparatuses 200 and 1000 including the same may be implemented in a chip size, and thus may be implemented in a relatively small size compared to the existing external light source system or a light source using a bonding method.

In addition, the multi-wavelength laser light source 100 according to the one or more embodiments described above and the silicon PIC apparatuses 200 and 1000 including the same may be implemented to be directly formed and contact on the silicon substrate 110 and thus be used as a multi-wavelength laser light source of an optoelectronic apparatus including a silicon PIC apparatus, and a system applied as above may be applied in various ways to a system requiring signal transmission such as chip-to-chip, chip-to-rack, rack-to-rack, etc.

In addition, the multi-wavelength laser light source 100 according to one or more embodiments and the silicon PIC apparatuses 200 and 1000 including the same may be formed directly on and contact the silicon substrate 110 and thus be used across an optoelectronic apparatus requiring an ultra-small multi-wavelength light source, and formed in a chip size including a multi-wavelength light source, and thus system cost reduction is possible.

The multi-wavelength laser light source 100 according to one or more embodiments and the silicon PIC apparatuses 200 and 1000 including the same use the laser element 120 directly grown based on silicon photonics instead of an external light source, which enables system miniaturization and may be applied to across silicon photonics systems and optical communications fields that require multi-wavelength light sources. For example, the multi-wavelength laser light source 100 according to one or more embodiments and the silicon PIC apparatuses 200 and 1000 including the same may be applied to various silicon photonics systems to which an optical communication system of a wavelength band of about 1550 nm is applied, from chip-to-chip to data center application.

For example, the multi-wavelength laser light source 100 according to one or more embodiments and the silicon PIC apparatuses 200 and 1000 including the same may be applied to a light source integrated PIC such as optical interconnection using WDM with respect to memory-to-memory communication, XPU (e.g., central processing unit (CPU), graphic processing unit (GPU), etc.)-to-memory communication, or XPU-to-XPU data transmission.

In addition, the multi-wavelength laser light source 100 according to various embodiments and the silicon PIC apparatuses 200 and 1000 including the same may be applied to all mobile and stationary devices requiring relatively large-capacity high-speed data transmission or broadband data transmission. The mobile and stationary devices may include, for example, automobiles, drones, robot vacuum cleaners, inspection equipment, industrial equipment, etc.

In addition, one or more embodiments may have the following configuration.

According to one or more embodiments, a multi-wavelength laser light source may include a silicon substrate including a multi-groove pattern in a partial region of the silicon substrate, a laser element based on a III-V compound semiconductor material and configured to generate a pump laser light, the laser element including a buffer layer crystal grown with respect to the multi-groove pattern and a light emitting layer structure epitaxially grown on the buffer layer, and including a quantum well structure that includes quantum barrier layers and quantum well layers stacked alternately multiple times, a micro-resonator on the silicon substrate, the micro-resonator having an anomalous GVD and being configured to generate a soliton frequency comb with respect to the pump laser light, and a waveguide on the silicon substrate, the waveguide being configured to enable optical coupling to the micro-resonator and to transmit the pump laser light input from the laser element to the micro-resonator, wherein the micro-resonator is further configured to generate laser light having a plurality of discontinuous wavelength bands of the soliton frequency comb.

In the multi-wavelength laser light source according to one or more embodiments, the micro-resonator may be a racetrack concentric resonator including an inner ring and an outer ring spaced apart from the inner ring.

In the multi-wavelength laser light source according to one or more embodiments, an effective light path length of the inner ring may be equal to an effective light path length of the outer ring.

In the multi-wavelength laser light source according to one or more embodiments, a ring cross-sectional width in the horizontal direction of the inner ring may be greater than a ring cross-sectional width of the outer ring.

In the multi-wavelength laser light source according to one or more embodiments, each of the inner ring and the outer ring may include at least one of Si₃N₄, Silica, LiNbO₃, Ta₂O₅, Si, GaP, AlN, AlGaAs, InP, or TiO₂.

In the multi-wavelength laser light source according to one or more embodiments, the light emitting structure may further include at least one of a first type semiconductor layer and a first clad layer between the buffer layer and the quantum well structure, and at least one of a second clad layer and a second type semiconductor layer of an opposite conductivity to a first type on the quantum well structure.

In the multi-wavelength laser light source according to one or more embodiments, the multi-wavelength laser light source may further include a superlattice layer based on and include a III-V compound semiconductor material between the buffer layer and the light emitting layer structure.

In the multi-wavelength laser light source according to one or more embodiments, the multi-groove pattern may have a multi-V groove shape.

According to one or more embodiments, a method of manufacturing a multi-wavelength laser light source may include forming a multi-groove pattern in a partial region of a silicon substrate, forming a laser element based on and include a III-V compound semiconductor material and configured to generate a pump laser light by forming a buffer layer crystal grown with respect to the multi-groove pattern and forming a light emitting layer structure epitaxially grown on the buffer layer, the light emitting layer including a quantum well structure formed by alternately stacking quantum barrier layers and quantum well layers multiple times, and forming a micro-resonator and a waveguide on the silicon substrate, the waveguide being configured to be optically coupled to the micro-resonator and to have an input end at a level of the quantum well structure of the laser element such that the laser element is configured to input the pump laser light, wherein the micro-resonator is formed to have an anomalous GVD and the micro-resonator is configured to generate a soliton frequency comb with respect to the pump laser light, and wherein the micro-resonator is further configured to generate laser light having a plurality of discontinuous wavelength bands of the soliton frequency comb.

In the method according to one or more embodiments, the micro-resonator and the waveguide may be formed in the same process step or different process steps.

In the method according to one or more embodiments, the micro-resonator may be a racetrack concentric resonator including an inner ring and an outer ring spaced apart from the inner ring.

In the method according to one or more embodiments, the micro-resonator may be formed such that an effective light path length of the inner ring is equal to an effective light path length of the outer ring.

In the method according to one or more embodiments, a ring cross-sectional width in the horizontal direction of the inner ring may be greater than a ring cross-sectional width of the outer ring.

In the method according to one or more embodiments, each of the inner ring and the outer ring may include at least one of Si₃N₄, Silica, LiNbO₃, Ta₂O₅, Si, GaP, AlN, AlGaAs, InP, or TiO₂.

In the method according to one or more embodiments, the forming of the laser element may further include forming at least one of a first type semiconductor layer and a first clad layer between the buffer layer and the quantum well structure, and forming at least one of a second clad layer and a second type semiconductor layer of the opposite conductivity to a first type on the quantum well structure.

In the method according to one or more embodiments, the forming of the laser element may further include forming a superlattice layer based on and including a III-V compound semiconductor material on the buffer layer before the forming of the light emitting layer structure.

In the method according to one or more embodiments, the multi-groove pattern may have a multi-V groove shape.

According to one or more embodiments, a silicon PIC apparatus may include a multi-wavelength laser light source including a laser element on a silicon substrate, the laser element being based on a III-V compound semiconductor material and configured to generate pump laser light, a micro-resonator on the silicon substrate, the micro-resonator being configured to generate a soliton frequency comb with respect to the pump laser light, and a waveguide on the silicon substrate, the waveguide being configured to enable optical coupling to the micro-resonator and to transmit the pump laser light input from the laser element to the micro-resonator, and

at least one optical element on the silicon substrate and optically connected to the multi-wavelength laser light source, wherein a multi-groove pattern is in a partial region of the silicon substrate, wherein the laser element includes a buffer layer crystal grown with respect to the multi-groove pattern of the silicon substrate, and a light emitting layer structure epitaxially grown on the buffer layer and may include a quantum well structure that includes quantum barrier layers and quantum well layers alternately stacked multiple times, wherein the micro-resonator has anomalous GVD on the silicon substrate, and is further configured to generate the soliton frequency comb with respect to the pump laser light, and wherein the micro-resonator included in the multi-wavelength laser light source is configured to generate laser light having a plurality of discontinuous wavelength bands of the soliton frequency comb.

In silicon PIC apparatus according to one or more embodiments, the micro-resonator may be a racetrack concentric resonator including an inner ring and an outer ring spaced apart from the inner ring.

In silicon PIC apparatus according to one or more embodiments, an effective light path length of the inner ring may be equal to an effective light path length of the outer ring.

In silicon PIC apparatus according to one or more embodiments, when a ring cross-sectional width in the horizontal direction of the inner ring is greater than a ring cross-sectional width of the outer ring.

In silicon PIC apparatus according to one or more embodiments, each of the inner ring and the outer ring may include at least one of Si₃N₄, Silica, LiNbO₃, Ta₂O₅, Si, GaP, AlN, AlGaAs, InP, or TiO₂.

In silicon PIC apparatus according to one or more embodiments, the light emitting structure of the laser element may further include at least one of a first type semiconductor layer and a first clad layer between the buffer layer and the quantum well structure, and at least one of a second clad layer and a second type semiconductor layer of an opposite conductivity to a first type on the quantum well structure.

In silicon PIC apparatus according to one or more embodiments, the laser element may further include a superlattice layer based on and including a III-V compound semiconductor material between the buffer layer and the light emitting layer structure.

In silicon PIC apparatus according to one or more embodiments, the multi-groove pattern may have a multi-V groove shape.

In silicon PIC apparatus according to one or more embodiments, the at least one optical element may include at least one light modulator configured to modulate at least some of the plurality of discontinuous wavelength bands of the laser light traveling through the waveguide and form a modulated soliton frequency comb.

In silicon PIC apparatus according to one or more embodiments, the at least one light modulator includes a ring resonator provided to be optically coupled to the waveguide.

According to a multi-wavelength laser light source according to one or more embodiments and a method of manufacturing the same, a multi-wavelength laser light source may include a laser element formed by direct growth on a multi-groove pattern of a silicon substrate and generating pump laser light, a micro-resonator formed on the silicon substrate to have anomalous dispersion characteristics through geometric structure adjustment and generating a soliton frequency comb with respect to the pump laser light, and a waveguide formed on the silicon substrate to transmit the pump laser light to the micro-resonator, and generate laser light Lc having a plurality of discontinuous wavelength bands of the soliton frequency comb. Accordingly, the multi-wavelength laser light source according to one or more embodiments may be directly formed on and contact the silicon substrate in a portion requiring a multi-wavelength light source, thereby implementing a relatively small low-power multi-wavelength laser light source.

In addition, the multi-wavelength laser light source according to one or more embodiments may be implemented in a form directly formed on and contact the silicon substrate and thus be used as a multi-wavelength light source of a silicon PIC apparatus or an optoelectronic apparatus including the same, and a system applied as above may be applied to various silicon photonics systems to which an optical communication system is applied, and may be applied in various ways to a system requiring signal transmission such as chip-to-chip, chip-to-rack, rack-to-rack, etc.

In addition, the multi-wavelength laser light source according to one or more embodiments and the silicon PIC apparatus with the same applied may be applied to a light source integrated PIC such as optical interconnection using WDM

In addition, the multi-wavelength laser light source according to one or more embodiments may be formed directly on the silicon substrate and thus be used across an optoelectronic apparatus requiring an ultra-small multi-wavelength light source, and formed in a chip size including a multi-wavelength light source, and thus system cost reduction is possible.

It should be understood that embodiments described herein should be considered in a descriptive sense only and not for purposes of limitation. Descriptions of features or aspects within each embodiment should typically be considered as available for other similar features or aspects in other embodiments. While embodiments have been described with reference to the figures, it will be understood by those of ordinary skill in the art that various changes in form and details may be made therein without departing from the spirit and scope as defined by the following claims and their equivalents.

What is claimed is:

1. A multi-wavelength laser light source comprising:
a silicon substrate comprising a multi-groove pattern in a partial region of the silicon substrate;
a laser element based on a III-V compound semiconductor material and configured to generate a pump laser light, the laser element comprising:
a buffer layer crystal grown with respect to the multi-groove pattern, and
a light emitting layer structure epitaxially grown on the buffer layer, and comprising a quantum well structure that comprises quantum barrier layers and quantum well layers stacked alternately multiple times;
a micro-resonator on the silicon substrate, the micro-resonator having anomalous group velocity dispersion (GVD) and being configured to generate a soliton frequency comb with respect to the pump laser light; and
a waveguide on the silicon substrate, the waveguide being configured to enable optical coupling to the micro-resonator and to transmit the pump laser light input from the laser element to the micro-resonator,
wherein the micro-resonator is further configured to generate laser light having a plurality of discontinuous wavelength bands of the soliton frequency comb.

2. The multi-wavelength laser light source of claim 1, wherein the micro-resonator comprises a racetrack concentric resonator comprising an inner ring and an outer ring spaced apart from the inner ring.

3. The multi-wavelength laser light source of claim 2, wherein an effective light path length of the inner ring is equal to an effective light path length of the outer ring.

4. The multi-wavelength laser light source of claim 2, wherein a ring cross-sectional width of the inner ring is greater than a ring cross-sectional width of the outer ring.

5. The multi-wavelength laser light source of claim 2, wherein each of the inner ring and the outer ring comprises at least one of silicon nitride (Si₃N₄), Silica, lithium niobium oxide (LiNbO₃), tantalum oxide (Ta₂O₅), silicon (Si), gallium phosphide (GaP), aluminum indium nitride (AlN), aluminum gallium arsenide (AlGaAs), indium phosphide (InP), or titanium oxide (TiO₂).

6. The multi-wavelength laser light source of claim 1, wherein the multi-groove pattern has a multi-V groove shape.

7. A method of manufacturing a multi-wavelength laser light source, the method comprising:
forming a multi-groove pattern in a partial region of a silicon substrate;
forming a laser element, based on a III-V compound semiconductor material and configured to generate a pump laser light, by forming a buffer layer crystal grown with respect to the multi-groove pattern and forming a light emitting layer structure epitaxially grown on the buffer layer, the light emitting layer structure comprising a quantum well structure formed by alternately stacking quantum barrier layers and quantum well layers multiple times; and
forming a micro-resonator and a waveguide on the silicon substrate, the waveguide being configured to be optically coupled to the micro-resonator and to have an input end at a level of the quantum well structure of the laser element such that the laser element is configured to input the pump laser light,
wherein the micro-resonator is formed to have anomalous group velocity dispersion (GVD), and the micro-resonator is configured to generate a soliton frequency comb with respect to the pump laser light, and
wherein the micro-resonator is further configured to generate laser light having a plurality of discontinuous wavelength bands of the soliton frequency comb.

8. The method of claim 7, wherein the micro-resonator and the waveguide are formed in a same process step or different process steps.

9. The method of claim 7, wherein the micro-resonator is a racetrack concentric resonator comprising an inner ring and an outer ring spaced apart from the inner ring.

10. The method of claim 9, wherein the micro-resonator is formed such that an effective light path length of the inner ring is equal to an effective light path length of the outer ring.

11. The method of claim 9, wherein a ring cross-sectional width of the inner ring is greater than a ring cross-sectional width of the outer ring.

12. The method of claim 9, wherein each of the inner ring and the outer ring comprises at least one of silicon nitride (Si₃N₄), Silica, lithium niobium oxide (LiNbO₃), tantalum oxide (Ta₂O₅), silicon (Si), gallium phosphide (GaP), aluminum indium nitride (AlN), aluminum gallium arsenide (AlGaAs), indium phosphide (InP), or titanium oxide (TiO₂).

13. The method of claim 7, wherein the multi-groove pattern has a multi-V groove shape.

14. A silicon photonic integrated circuit (PIC) apparatus comprising:
a multi-wavelength laser light source comprising:
a laser element on a silicon substrate, the laser element being based on a III-V compound semiconductor material and configured to generate pump laser light;
a micro-resonator on the silicon substrate, the micro-resonator being configured to generate a soliton frequency comb with respect to the pump laser light; and
a waveguide on the silicon substrate, the waveguide being configured to enable optical coupling to the micro-resonator and to transmit the pump laser light input from the laser element to the micro-resonator; and
at least one optical element on the silicon substrate and optically connected to the multi-wavelength laser light source,
wherein a multi-groove pattern is in a partial region of the silicon substrate,
wherein the laser element comprises a buffer layer crystal grown with respect to the multi-groove pattern of the silicon substrate, and a light emitting layer structure epitaxially grown on the buffer layer and comprising a quantum well structure that comprises quantum barrier layers and quantum well layers alternately stacked multiple times,
wherein the micro-resonator has anomalous group velocity dispersion (GVD) on the silicon substrate, and is further configured to generate the soliton frequency comb with respect to the pump laser light, and
wherein the micro-resonator included in the multi-wavelength laser light source is configured to generate laser light having a plurality of discontinuous wavelength bands of the soliton frequency comb.

15. The silicon PIC apparatus of claim 14, wherein the micro-resonator is a racetrack concentric resonator comprising an inner ring and an outer ring spaced apart from the inner ring.

16. The silicon PIC apparatus of claim 15, wherein an effective light path length of the inner ring is equal to an effective light path length of the outer ring.

17. The silicon PIC apparatus of claim 15, wherein a ring cross-sectional width of the inner ring is greater than a ring cross-sectional width of the outer ring.

18. The silicon PIC apparatus of claim 15, wherein each of the inner ring and the outer ring comprises at least one of silicon nitride (Si₃N₄), Silica, lithium niobium oxide (LiNbO₃), tantalum oxide (Ta₂O₅), silicon (Si), gallium phosphide (GaP), aluminum indium nitride (AlN), aluminum gallium arsenide (AlGaAs), indium phosphide (InP), or titanium oxide (TiO₂).

19. The silicon PIC apparatus of claim 14, wherein the multi-groove pattern has a multi-V groove shape.

20. The silicon PIC apparatus of claim 14, wherein the at least one optical element comprises at least one light modulator configured to modulate at least some of the plurality of discontinuous wavelength bands of the laser light traveling through the waveguide and form a modulated soliton frequency comb.
